(19) United States
(12) Patent Application Publication
(10) Pub. No.: US 2025/0141601 A1
(43) Pub. Date: May 1, 2025

(54) METHODS AND APPARATUS FOR SELECTIVE RETRANSMISSION

(71) Applicant: Huawei Technologies Co., Ltd., Shenzhen (CN)

(72) Inventors: Aman Jassal, Stittsville (CA); Amine Maaref, Ottawa (CA); Jianglei Ma, Ottawa (CA)

(21) Appl. No.: 18/973,919

(22) Filed: Dec. 9, 2024

Related U.S. Application Data
(63) Continuation of application No. PCT/CN2022/097758, filed on Jun. 9, 2022.

(51) Int. Cl. H04L 1/1809; H04L 1/00; H04L 1/1607

(52) U.S. Cl. CPC H04L 1/1809; H04L 1/0014; H04L 1/0057; H04L 1/1614

(57) ABSTRACT

In aspects of a Selective Retransmission Request (SeRQ) protocol proposed herein for wireless communication, a UE may group Retransmission Request (RTQ) feedback information bits for a plurality of transport blocks (TBs). The RTQ feedback information may be understood to indicate, to a non-terrestrial transmit receive point (NT-TRP), which TBs, among the plurality of TBs in the window, were not decoded properly. UEs may generate RTQ feedback information bits for a group of TBs received during a single window or TBs that have been received during multiple, distinct windows. The generation, by the UEs, of the RTQ feedback information bits for a group of TBs may be encoded based on, e.g., source coding, codebooks, binomial coefficients, etc. Upon receipt of a retransmitted version of a given TB, the UE may combine previously received bits of the given TB with the retransmitted TB version of the given TB.

### CROSS-REFERENCE TO RELATED APPLICATION

This application is a continuation of International Application No. PCT/CN2022/097758, filed on Jun. 9, 2022, which is hereby incorporated by reference in its entirety.

### TECHNICAL FIELD

The present disclosure relates, generally, to selective retransmission of transport blocks and, in particular embodiments, to the provision of feedback regarding success of decoding transport blocks and the reaction to the receipt of the feedback.

### BACKGROUND

Current radio access technologies, such as fourth generation (4G) long-term evolution (LTE) cellular systems and fourth generation (5G) new radio (NR) are based on usage of the established Hybrid Automatic Repeat Request (HARQ) protocol, which is, itself, based on the known Stop-And-Wait protocol. In the Stop-And-Wait protocol, a transmitter sends a packet to a receiver and waits for the receiver to send an acknowledgement (positive or negative) before sending a new packet. If no acknowledgement is received by the transmitter, the transmitter simply retransmits the packet. Rather than processing packets one-at-a-time, multiple HARQ processes operate in parallel in a staggered fashion, allowing for continuous data reception.

In addition to using the Stop-And-Wait protocol, there are procedures in place to handle situations such as downlink control information (DCI) format misdetection and uplink control information (UCI) format misdetection. In 5G NR, at every defined time slot, a communication electric device (ED, also called user equipment or “UE”) may be configured to monitor physical downlink control channel (PDCCH) monitoring occasions. At these monitoring occasions, the UE may find a PDCCH that schedules (i.e., the PDCCH indicates the physical resources used to transmit) a physical downlink shared channel (PDSCH) transmission, such as a unicast PDSCH transmission. Due to poor channel conditions, the UE may fail to detect PDCCH transmissions, which may lead to a DCI format misdetection. If a PDCCH scheduling a PDSCH transmission has not been detected, then the UE has no reason to generate HARQ-ACK information. Due to poor channel conditions, a network entity may fail to detect PUCCH transmissions from the UE, which may lead to a UCI format misdetection. Different PUCCH Formats may be selected, by the UE, based on a number of UCI bits in a given to-be-transmitted UCI, where the upper and lower bounds of UCI bits can be specified or configured by a network entity.

### SUMMARY

In aspects of a Selective Retransmission Request (SeRQ) protocol, proposed herein, a UE may group Retransmission Request (RTQ) feedback information bits for a plurality of transport blocks (TBs). The RTQ feedback information may be understood to indicate, to a non-terrestrial transmit receive point (NT-TRP), which TBs, among the plurality of TBs in the window, were not decoded properly. UEs may generate RTQ feedback information bits for a group of TBs. The NT-TRP may selectively retransmit the TBs that, according to the feedback, were not decoded properly.

In current 5G NR standards, a presence of multiple parallel HARQ process implementation is relied upon to ensure continuous data reception at the UE, where the number of HARQ processes is dimensioned to match the round-trip time of the communication system. This approach may be regarded as delay intolerant.

When a communication system has a large propagation delay, an ill-dimensioned Soft Buffer, at the UE, may be shown to result in non-continuous data reception at the UE side. Accordingly, problems crop up with HARQ outages and the bottlenecking based on a mismatch between the propagation delay in the communication system and the dimensioning of the Soft Buffer.

The proposed Selective Retransmission Protocol helps tackle the delay tolerance issue by not waiting for an acknowledgement from the receiver before sending new packets to the receiver.

Conveniently, aspects of the present application relate to compressing uplink feedback into shorter coded sequences. By only generating feedback for partitions where erroneous TBs are located, a reduced payload for the uplink feedback may be realized along with a reduced uplink power consumption. When erroneous TBs are contiguous, the UE may be limited to transmitting only one physical uplink control channel carrying feedback. Thanks to redundant retransmissions, the probability of erroneous TB detection is reduced, thereby helping to reduce the volume of feedback transmitted by the UE.

According to an aspect of the present disclosure, there is provided a method. The method includes receiving a plurality of transport blocks in a window, the window predefined to include a given number of transport blocks, decoding at least one transport block in the plurality of transport blocks and transmitting feedback corresponding to a subset of transport blocks, from the plurality of transport blocks in the window, that have not been decoded correctly. Additionally, there is provided an apparatus adapted to carry out this method.

In an embodiment in accordance with the preceding aspects, each transport block among the plurality of transport blocks is received in a physical downlink shared channel reception occasion.

In an embodiment in accordance with the preceding aspects or embodiments, the method further comprises encoding the feedback using a bitmap.

In an embodiment in accordance with the preceding aspects or embodiments, the method further comprises encoding the feedback using source coding. Optionally, using source coding comprises: partitioning the window into a plurality of groups of transport blocks; and generating the feedback by encoding, for a group in the plurality of groups, a code word selected within a codebook, wherein the code word is representative of the positions, in the group, of transport blocks that have not been decoded correctly in view of the number of transport blocks in the group.

Optionally, the codebook comprises a plurality of code words, wherein each code word in the plurality of code words is associated with an input symbol from a dictionary, the dictionary corresponding to a subset of transport blocks not having been decoded correctly.

Optionally, the dictionary comprises a plurality of input symbols, each input symbol: corresponding to a given probability of not decoding a transport block correctly; and representing a position, within the group, of a transport block that has not been decoded correctly.

Optionally, the method further comprises selecting the codebook from a plurality of codebooks. Optionally, the selecting is based on a quantity of consecutive transport blocks that have not been decoded correctly.

In an embodiment in accordance with the preceding aspects or embodiments, the method further comprises: partitioning the window into a plurality of groups, each group in the plurality of groups having a given number of transport blocks; defining a codebook to contain code words corresponding to the positions of transport blocks that have not been decoded correctly in view of the given number of transport blocks; and generating the feedback by selecting a code word within the codebook, wherein the code word is representative of the positions, in the group, of the transport blocks that have not been decoded correctly. Optionally, the method further comprises selecting a given binomial coefficient from a set of binomial coefficients, the set of binomial coefficients related to the given number of transport blocks in each group, the number of bits in the code word selected on the basis of the given binomial coefficient. Optionally, the method further comprises associating, with the feedback, an indicator of a half of the set of binomial coefficients from which the given binomial coefficient has been selected.

In an embodiment in accordance with the preceding aspects or embodiments, transmitting the feedback comprises generating an uplink control information that includes the feedback. Optionally, generating the uplink control information comprises associating the feedback with an identifier for the window.

In an embodiment in accordance with the preceding aspects or embodiments, transmitting the feedback comprises generating a representation of a number of contiguous transport blocks that have not been decoded correctly.

In an embodiment in accordance with the preceding aspects or embodiments, the method further comprises: dividing the window into a plurality of partitions; and generating the feedback as a partition bitmap for the window, the partition bitmap: having a number of bits corresponding to the number of partitions in the plurality of partitions; and including a bit set to identify each of the partitions in which transport blocks that have not been decoded correctly are located.

In an embodiment in accordance with the preceding aspects or embodiments, the feedback comprises an indication of a number of transport blocks that have not been decoded correctly.

In an embodiment in accordance with the preceding aspects or embodiments, transmitting the feedback comprises transmitting the feedback in a physical uplink control channel.

In an embodiment in accordance with the preceding aspects or embodiments, the feedback indicates a location, in the window, for each transport block that that has not been decoded correctly.

In an embodiment in accordance with the preceding aspects or embodiments, the subset of transport blocks that have not been decoded correctly form a contiguous subset of erroneous transport blocks and the feedback comprises: an indication of an index for a first transport block in the subset of erroneous transport blocks; and an indication of a number of transport blocks in the subset of erroneous transport blocks. Optionally, the method further comprises encoding the feedback.

According to an aspect of the present disclosure, there is provided a method. The method includes transmitting a plurality of transport blocks in a window, the window predefined to include a given number of transport blocks and receiving feedback corresponding to a subset of transport blocks, from the plurality of transport blocks in the window, that have not been decoded correctly. Additionally, there is provided an apparatus adapted to carry out this method.

In an embodiment in accordance with the preceding aspects, the method further comprises: decoding the feedback, wherein the feedback has been encoded using source coding. Optionally, using source coding comprises: partitioning the window into a plurality of groups of transport blocks; and generating the feedback by encoding, for a group in the plurality of groups, a code word selected within a codebook, wherein the code word is representative of the positions, in the group, of transport blocks that have not been decoded correctly in view of the number of transport blocks in the group.

Optionally, the codebook comprises a plurality of code words, wherein each code word in the plurality of code words is associated with an input symbol from a dictionary, the dictionary corresponding to a subset of transport blocks not having been decoded correctly.

Optionally, the dictionary comprises a plurality of input symbols, each input symbol: corresponding to a given probability of not decoding a transport block correctly; and representing a position, within the group, of a transport block that has not been decoded correctly. Optionally, the decoding comprises selecting the codebook from a plurality of codebooks.

In an embodiment in accordance with the preceding aspects or embodiments, the method further comprises: decoding the feedback by determining a code word within a codebook, wherein the code word is representative of positions, within a group of transport blocks, of transport blocks that have not been decoded correctly. Optionally, the feedback has been encoded by selecting a given binomial coefficient from a set of binomial coefficients, the set of binomial coefficients related to the given number of transport blocks in each group, the number of bits in the code word selected on the basis of the given binomial coefficient. Optionally, the feedback is associated with an indicator of a half of the set of binomial coefficients from which the given binomial coefficient has been selected.

In an embodiment in accordance with the preceding aspects or embodiments, receiving the feedback comprises receiving an uplink control information that includes the feedback.

### BRIEF DESCRIPTION OF THE DRAWINGS

For a more complete understanding of the present embodiments, and the advantages thereof, reference is now made, by way of example, to the following descriptions taken in conjunction with the accompanying drawings, in which:

FIG. 1 illustrates, in a schematic diagram, a communication system in which embodiments of the disclosure may occur, the communication system includes multiple example electronic devices and multiple example transmit receive points along with various networks;

FIG. 2 illustrates, in a block diagram, the communication system of FIG. 1, the communication system includes multiple example electronic devices, an example terrestrial transmit receive point and an example non-terrestrial transmit receive point along with various networks;

FIG. 3 illustrates, as a block diagram, elements of an example electronic device of FIG. 2, elements of an example terrestrial transmit receive point of FIG. 2 and elements of an example non-terrestrial transmit receive point of FIG. 2, in accordance with aspects of the present application;

FIG. 4 illustrates, as a block diagram, various modules that may be included in an example electronic device, an example terrestrial transmit receive point and an example non-terrestrial transmit receive point, in accordance with aspects of the present application;

FIG. 5 illustrates, as a block diagram, a sensing management function, in accordance with aspects of the present application;

FIG. 6 illustrates an example of a window of 40 transport blocks with non-contiguous erroneously received transport blocks;

FIG. 7 illustrates a Huffman code probability table;

FIG. 8 illustrates an example of a window of 40 transport blocks with contiguous erroneously received transport blocks;

FIG. 9 illustrates an example codebook for four contiguous erroneous transport blocks;

FIG. 10 illustrates two windows of 40 transport blocks that may be understood to map to a so-called Soft Buffer at the UE, each window includes a plurality of non-contiguous erroneously-received transport blocks;

FIG. 11 illustrates a set of uplink control information bits for one of the windows of FIG. 10 and a set of uplink control information bits for the other of the windows of FIG. 10, in accordance with aspects of the present application;

FIG. 12 illustrates a set of uplink control information bits for one of the windows of FIG. 10 and a set of uplink control information bits for the other of the windows of FIG. 10 as an alternative to the sets of FIG. 11, in accordance with aspects of the present application;

FIG. 13 illustrates example set of uplink control information bits including a Window ID, a number of bits per symbol, a measured BLER and a plurality of sets of feedback, in accordance with aspects of the present application;

FIG. 14 illustrates a set of uplink control information bits for one of the windows of FIG. 10 and a set of uplink control information bits for the other of the windows of FIG. 10, in accordance with aspects of the present application;

FIG. 15 illustrates a set of uplink control information bits for one of the windows of FIG. 10 and a set of uplink control information bits for the other of the windows of FIG. 10 as an alternative to the sets of FIG. 11, in accordance with aspects of the present application;

FIG. 16 illustrates a set of uplink control information bits for one of the windows of FIG. 10 and a set of uplink control information bits for the other of the windows of FIG. 10 as an alternative to the sets of FIG. 11, in accordance with aspects of the present application;

FIG. 17 illustrates two windows of 40 transport blocks that may be understood to map to a so-called Soft Buffer at the UE, each window includes a plurality of contiguous erroneously-received transport blocks;

FIG. 18 illustrates a set of uplink control information bits for one of the windows of FIG. 17 and a set of uplink control information bits for the other of the windows of FIG. 17, in accordance with aspects of the present application;

FIG. 19 illustrates a set of uplink control information bits for one of the windows of FIG. 10 and a set of uplink control information bits for the other of the windows of FIG. 10 as an alternative to the sets of FIG. 11, in accordance with aspects of the present application;

FIG. 20 illustrates a single window with two sets of contiguous erroneous transport blocks;

FIG. 21 illustrates a set of uplink control information bits for the window of FIG. 20, in accordance with aspects of the present application;

FIG. 22 illustrates an example of a transmission event followed by a reception event;

FIG. 23 illustrates an example of a transmission of feedback followed by a retransmission triggered by receipt of the feedback for a high-priority transport block, in accordance with aspects of the present application;

FIG. 24 illustrates an example of a transmission event followed by a reception event followed by a transmission of feedback for a low-priority transport block, in accordance with aspects of the present application;

FIG. 25A illustrates an example of a transmission of feedback followed by a transmission physical downlink control channel, in accordance with aspects of the present application;

FIG. 25B illustrates an example physical downlink control channel, as transmitted in FIG. 25A, jointly carrying three redundancy versions of a transport block with a particular Packet ID, in accordance with aspects of the present application;

FIG. 26 illustrates an example of a transmission event, for transport blocks containing a plurality of packets of distinct priority, followed by a reception event followed by a transmission of feedback for a high-priority transport block, in accordance with aspects of the present application.

### DETAILED DESCRIPTION OF THE EMBODIMENTS

For illustrative purposes, specific example embodiments will now be explained in greater detail in conjunction with the figures.

The embodiments set forth herein represent information sufficient to practice the claimed subject matter and illustrate ways of practicing such subject matter. Upon reading the following description in light of the accompanying figures, those of skill in the art will understand the concepts of the claimed subject matter and will recognize applications of these concepts not particularly addressed herein. It should be understood that these concepts and applications fall within the scope of the disclosure and the accompanying claims.

Moreover, it will be appreciated that any module, component, or device disclosed herein that executes instructions may include, or otherwise have access to, a non-transitory computer/processor readable storage medium or media for storage of information, such as computer/processor readable instructions, data structures, program modules and/or other data. A non-exhaustive list of examples of non-transitory computer/processor readable storage media includes magnetic cassettes, magnetic tape, magnetic disk storage or other magnetic storage devices, optical disks such as compact disc read-only memory (CD-ROM), digital video discs or digital versatile discs (i.e., DVDs), Blu-ray Disc™, or other optical storage, volatile and non-volatile, removable and non-removable media implemented in any method or technology, random-access memory (RAM), read-only memory (ROM), electrically erasable programmable read-only memory (EEPROM), flash memory or other memory technology. Any such non-transitory computer/processor storage media may be part of a device or accessible or connectable thereto. Computer/processor readable/executable instructions to implement an application or module described herein may be stored or otherwise held by such non-transitory computer/processor readable storage media.

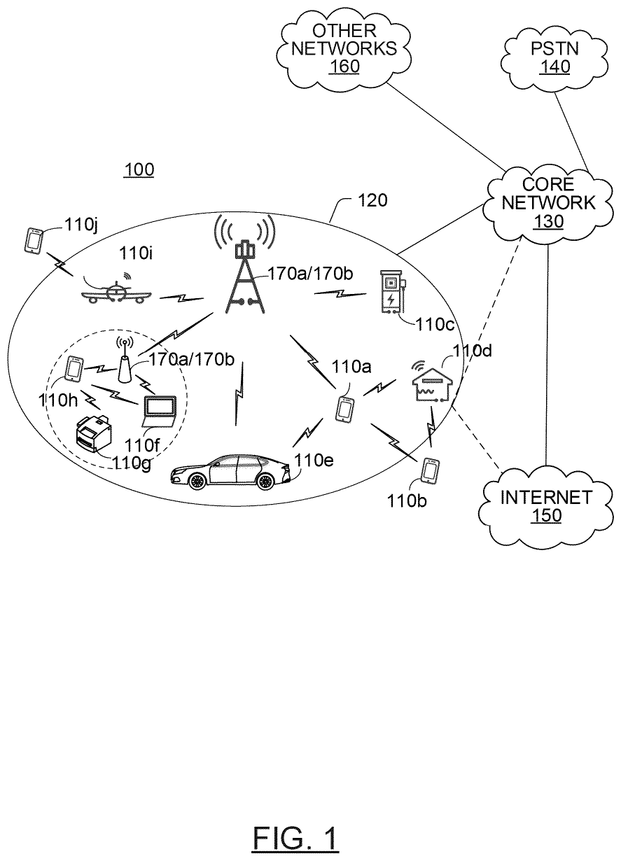

Referring to FIG. 1, as an illustrative example without limitation, a simplified schematic illustration of a communication system is provided. The communication system 100 comprises a radio access network 120. The radio access network 120 may be a next generation (e.g., sixth generation, “6G,” or later) radio access network, or a legacy (e.g., 5G, 4G, 3G or 2G) radio access network. One or more communication electric device (ED) 110a, 110b, 110c, 110d, 110e, 110f, 110g, 110h, 110i, 110j (generically referred to as 110) may be interconnected to one another or connected to one or more network nodes (170a, 170b, generically referred to as 170) in the radio access network 120. A core network 130 may be a part of the communication system and may be dependent or independent of the radio access technology used in the communication system 100. Also the communication system 100 comprises a public switched telephone network (PSTN) 140, the internet 150, and other networks 160.

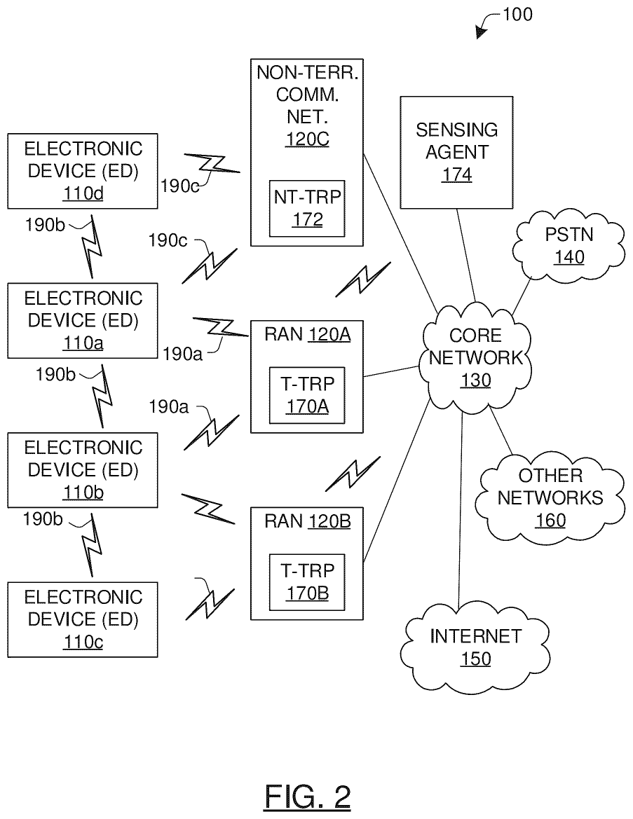

FIG. 2 illustrates an example communication system 100. In general, the communication system 100 enables multiple wireless or wired elements to communicate data and other content. The purpose of the communication system 100 may be to provide content, such as voice, data, video, and/or text, via broadcast, multicast and unicast, etc. The communication system 100 may operate by sharing resources, such as carrier spectrum bandwidth, between its constituent elements. The communication system 100 may include a terrestrial communication system and/or a non-terrestrial communication system. The communication system 100 may provide a wide range of communication services and applications (such as earth monitoring, remote sensing, passive sensing and positioning, navigation and tracking, autonomous delivery and mobility, etc.). The communication system 100 may provide a high degree of availability and robustness through a joint operation of a terrestrial communication system and a non-terrestrial communication system. For example, integrating a non-terrestrial communication system (or components thereof) into a terrestrial communication system can result in what may be considered a heterogeneous network comprising multiple layers. Compared to conventional communication networks, the heterogeneous network may achieve better overall performance through efficient multi-link joint operation, more flexible functionality sharing and faster physical layer link switching between terrestrial networks and non-terrestrial networks.

The terrestrial communication system and the non-terrestrial communication system could be considered sub-systems of the communication system. In the example shown in FIG. 2, the communication system 100 includes electronic devices (ED) 110a, 110b, 110c, 110d (generically referred to as ED 110), radio access networks (RANs) 120a, 120b, a non-terrestrial communication network 120c, a core network 130, a public switched telephone network (PSTN) 140, the Internet 150 and other networks 160. The RANs 120a, 120b include respective base stations (BSs) 170a, 170b, which may be generically referred to as terrestrial transmit and receive points (T-TRPs) 170a, 170b. The non-terrestrial communication network 120c includes an access node 172, which may be generically referred to as a non-terrestrial transmit and receive point (NT-TRP) 172.

Any ED 110 may be alternatively or additionally configured to interface, access, or communicate with any T-TRP 170a, 170b and NT-TRP 172, the Internet 150, the core network 130, the PSTN 140, the other networks 160, or any combination of the preceding. In some examples, the ED 110a may communicate an uplink and/or downlink transmission over a terrestrial air interface 190a with T-TRP 170a. In some examples, the EDs 110a, 110b, 110c and 110d may also communicate directly with one another via one or more sidelink air interfaces 190b. In some examples, the ED nod may communicate an uplink and/or downlink transmission over a non-terrestrial air interface 190c with NT-TRP 172.

The air interfaces 190a and 190b may use similar communication technology, such as any suitable radio access technology. For example, the communication system 100 may implement one or more channel access methods, such as code division multiple access (CDMA), space division multiple access (SDMA), time division multiple access (TDMA), frequency division multiple access (FDMA), orthogonal FDMA (OFDMA), single-carrier FDMA (SC-FDMA) or Direct Fourier Transform spread OFDMA (DFT-OFDMA) in the air interfaces 190a and 190b. The air interfaces 190a and 190b may utilize other higher dimension signal spaces, which may involve a combination of orthogonal and/or non-orthogonal dimensions.

The non-terrestrial air interface 190c can enable communication between the ED 110d and one or multiple NT-TRPs 172 via a wireless link or simply a link. For some examples, the link is a dedicated connection for unicast transmission, a connection for broadcast transmission, or a connection between a group of EDs 110 and one or multiple NT-TRPs 175 for multicast transmission.

The RANs 120a and 120b are in communication with the core network 130 to provide the EDs 110a, 110b, 110c with various services such as voice, data and other services. The RANs 120a and 120b and/or the core network 130 may be in direct or indirect communication with one or more other RANs (not shown), which may or may not be directly served by core network 130 and may, or may not, employ the same radio access technology as RAN 120a, RAN 120b or both. The core network 130 may also serve as a gateway access between (i) the RANs 120a and 120b or the EDs 110a, 110b, 110c or both, and (ii) other networks (such as the PSTN 140, the Internet 150, and the other networks 160). In addition, some or all of the EDs 110a, 110b, 110c may include functionality for communicating with different wireless networks over different wireless links using different wireless technologies and/or protocols. Instead of wireless communication (or in addition thereto), the EDs 110a, 110b, 110c may communicate via wired communication channels to a service provider or switch (not shown) and to the Internet 150. The PSTN 140 may include circuit switched telephone networks for providing plain old telephone service (POTS). The Internet 150 may include a network of computers and subnets (intranets) or both and incorporate protocols, such as Internet Protocol (IP), Transmission Control Protocol (TCP), User Datagram Protocol (UDP). The EDs 110a, 110b, 110c may be multimode devices capable of operation according to multiple radio access technologies and may incorporate multiple transceivers necessary to support such.

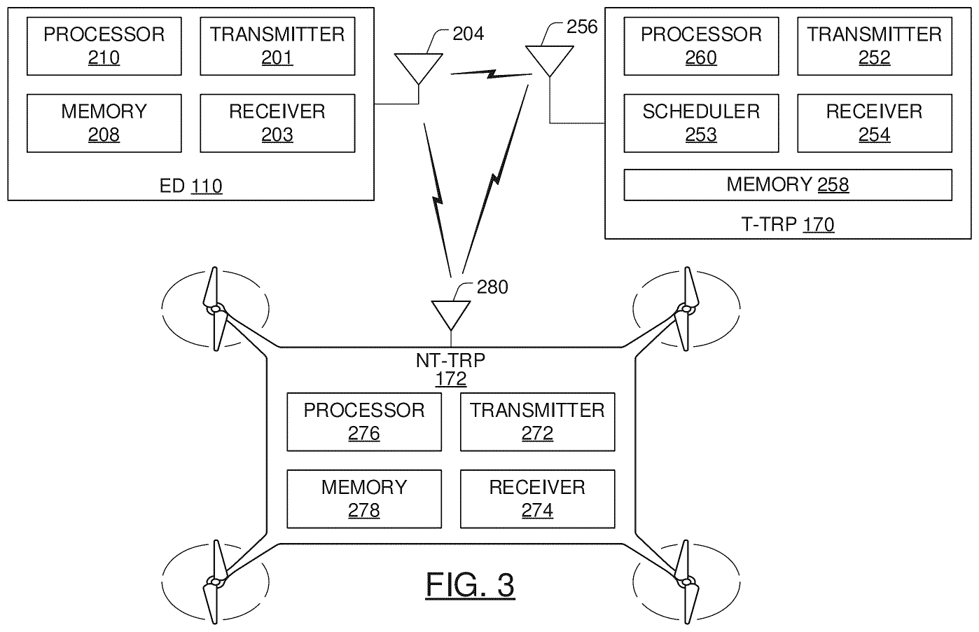

FIG. 3 illustrates another example of an ED no and a base station 170a, 170b and/or 170c. The ED no is used to connect persons, objects, machines, etc. The ED no may be widely used in various scenarios, for example, cellular communications, device-to-device (D2D), vehicle to everything (V2X), peer-to-peer (P2P), machine-to-machine (M2M), machine-type communications (MTC), Internet of things (IOT), virtual reality (VR), augmented reality (AR), mixed reality (MR), metaverse, digital twin, industrial control, self-driving, remote medical, smart grid, smart furniture, smart office, smart wearable, smart transportation, smart city, drones, robots, remote sensing, passive sensing, positioning, navigation and tracking, autonomous delivery and mobility, etc.

Each ED 110 represents any suitable end user device for wireless operation and may include such devices (or may be referred to) as a user equipment/device (UE), a wireless transmit/receive unit (WTRU), a mobile station, a fixed or mobile subscriber unit, a cellular telephone, a station (STA), a machine type communication (MTC) device, a personal digital assistant (PDA), a smartphone, a laptop, a computer, a tablet, a wireless sensor, a consumer electronics device, wearable devices such as a watch, head mounted equipment, a pair of glasses, a smart book, a vehicle, a car, a truck, a bus, a train, or an IoT device, an industrial device, or apparatus (e.g., communication module, modem, or chip) in the forgoing devices, among other possibilities. Future generation EDs 110 may be referred to using other terms. The base stations 170a and 170b each T-TRPs and will, hereafter, be referred to as T-TRP 170. Also shown in FIG. 3, a NT-TRP will hereafter be referred to as NT-TRP 172. Each ED 110 connected to the T-TRP 170 and/or the NT-TRP 172 can be dynamically or semi-statically turned-on (i.e., established, activated or enabled), turned-off (i.e., released, deactivated or disabled) and/or configured in response to one of more of: connection availability; and connection necessity.

The ED 110 includes a transmitter 201 and a receiver 203 coupled to one or more antennas 204. Only one antenna 204 is illustrated. One, some, or all of the antennas 204 may, alternatively, be panels. The transmitter 201 and the receiver 203 may be integrated, e.g., as a transceiver. The transceiver is configured to modulate data or other content for transmission by the at least one antenna 204 or by a network interface controller (NIC). The transceiver may also be configured to demodulate data or other content received by the at least one antenna 204. Each transceiver includes any suitable structure for generating signals for wireless or wired transmission and/or processing signals received wirelessly or by wire. Each antenna 204 includes any suitable structure for transmitting and/or receiving wireless or wired signals.

The ED 110 includes at least one memory 208. The memory 208 stores instructions and data used, generated, or collected by the ED 110. For example, the memory 208 could store software instructions or modules configured to implement some or all of the functionality and/or embodiments described herein and that are executed by one or more processing unit(s) (e.g., a processor 210). Each memory 208 includes any suitable volatile and/or non-volatile storage and retrieval device(s). Any suitable type of memory may be used, such as random access memory (RAM), read only memory (ROM), hard disk, optical disc, subscriber identity module (SIM) card, memory stick, secure digital (SD) memory card, on-processor cache and the like.

The ED 110 may further include one or more input/output devices (not shown) or interfaces (such as a wired interface to the Internet 150 in FIG. 1). The input/output devices permit interaction with a user or other devices in the network. Each input/output device includes any suitable structure for providing information to, or receiving information from, a user, such as through operation as a speaker, a microphone, a keypad, a keyboard, a display or a touch screen, including network interface communications.

The ED 110 includes the processor 210 for performing operations including those operations related to preparing a transmission for uplink transmission to the NT-TRP 172 and/or the T-TRP 170, those operations related to processing downlink transmissions received from the NT-TRP 172 and/or the T-TRP 170, and those operations related to processing sidelink transmission to and from another ED 110. Processing operations related to preparing a transmission for uplink transmission may include operations such as encoding, modulating, transmit beamforming and generating symbols for transmission. Processing operations related to processing downlink transmissions may include operations such as receive beamforming, demodulating and decoding received symbols. Depending upon the embodiment, a downlink transmission may be received by the receiver 203, possibly using receive beamforming, and the processor 210 may extract signaling from the downlink transmission (e.g., by detecting and/or decoding the signaling). An example of signaling may be a reference signal transmitted by the NT-TRP 172 and/or by the T-TRP 170. In some embodiments, the processor 210 implements the transmit beamforming and/or the receive beamforming based on the indication of beam direction, e.g., beam angle information (BAI), received from the T-TRP 170. In some embodiments, the processor 210 may perform operations relating to network access (e.g., initial access) and/or downlink synchronization, such as operations relating to detecting a synchronization sequence, decoding and obtaining the system information, etc. In some embodiments, the processor 210 may perform channel estimation, e.g., using a reference signal received from the NT-TRP 172 and/or from the T-TRP 170.

Although not illustrated, the processor 210 may form part of the transmitter 201 and/or part of the receiver 203. Although not illustrated, the memory 208 may form part of the processor 210.

The processor 210, the processing components of the transmitter 201 and the processing components of the receiver 203 may each be implemented by the same or different one or more processors that are configured to execute instructions stored in a memory (e.g., the in memory 208). Alternatively, some or all of the processor 210, the processing components of the transmitter 201 and the processing components of the receiver 203 may each be implemented using dedicated circuitry, such as a programmed field-programmable gate array (FPGA), a Central Processing Unit (CPU), a graphical processing unit (GPU), or an application-specific integrated circuit (ASIC).

The T-TRP 170 may be known by other names in some implementations, such as a base station, a base transceiver station (BTS), a radio base station, a network node, a network device, a device on the network side, a transmit/receive node, a Node B, an evolved NodeB (eNodeB or eNB), a Home eNodeB, a next Generation NodeB (gNB), a transmission point (TP), a site controller, an access point (AP), a wireless router, a relay station, a remote radio head, a terrestrial node, a terrestrial network device, a terrestrial base station, a base band unit (BBU), a remote radio unit (RRU), an active antenna unit (AAU), a remote radio head (RRH), a central unit (CU), a distribute unit (DU), a positioning node, among other possibilities. The T-TRP 170 may be a macro BS, a pico BS, a relay node, a donor node, or the like, or combinations thereof. The T-TRP 170 may refer to the forgoing devices or refer to apparatus (e.g., a communication module, a modem or a chip) in the forgoing devices.

In some embodiments, the parts of the T-TRP 170 may be distributed. For example, some of the modules of the T-TRP 170 may be located remote from the equipment that houses antennas 256 for the T-TRP 170, and may be coupled to the equipment that houses antennas 256 over a communication link (not shown) sometimes known as front haul, such as common public radio interface (CPRI). Therefore, in some embodiments, the term T-TRP 170 may also refer to modules on the network side that perform processing operations, such as determining the location of the ED 110, resource allocation (scheduling), message generation, and encoding/decoding, and that are not necessarily part of the equipment that houses antennas 256 of the T-TRP 170. The modules may also be coupled to other T-TRPs. In some embodiments, the T-TRP 170 may actually be a plurality of T-TRPs that are operating together to serve the ED 110, e.g., through the use of coordinated multipoint transmissions.

As illustrated in FIG. 3, the T-TRP 170 includes at least one transmitter 252 and at least one receiver 254 coupled to one or more antennas 256. Only one antenna 256 is illustrated. One, some, or all of the antennas 256 may, alternatively, be panels. The transmitter 252 and the receiver 254 may be integrated as a transceiver. The T-TRP 170 further includes a processor 260 for performing operations including those related to: preparing a transmission for downlink transmission to the ED 110; processing an uplink transmission received from the ED 110; preparing a transmission for backhaul transmission to the NT-TRP 172; and processing a transmission received over backhaul from the NT-TRP 172. Processing operations related to preparing a transmission for downlink or backhaul transmission may include operations such as encoding, modulating, precoding (e.g., multiple input multiple output, “MIMO,” precoding), transmit beamforming and generating symbols for transmission. Processing operations related to processing received transmissions in the uplink or over backhaul may include operations such as receive beamforming, demodulating received symbols and decoding received symbols. The processor 260 may also perform operations relating to network access (e.g., initial access) and/or downlink synchronization, such as generating the content of synchronization signal blocks (SSBs), generating the system information, etc. In some embodiments, the processor 260 also generates an indication of beam direction, e.g., BAI, which may be scheduled for transmission by a scheduler 253. The processor 260 performs other network-side processing operations described herein, such as determining the location of the ED 110, determining where to deploy the NT-TRP 172, etc. In some embodiments, the processor 260 may generate signaling, e.g., to configure one or more parameters of the ED 110 and/or one or more parameters of the NT-TRP 172. Any signaling generated by the processor 260 is sent by the transmitter 252. Note that “signaling,” as used herein, may alternatively be called control signaling. Dynamic signaling may be transmitted in a control channel, e.g., a physical downlink control channel (PDCCH) and static, or semi-static, higher layer signaling may be included in a packet transmitted in a data channel, e.g., in a physical downlink shared channel (PDSCH).

The scheduler 253 may be coupled to the processor 260. The scheduler 253 may be included within, or operated separately from, the T-TRP 170. The scheduler 253 may schedule uplink, downlink and/or backhaul transmissions, including issuing scheduling grants and/or configuring scheduling-free (“configured grant”) resources. The T-TRP 170 further includes a memory 258 for storing information and data. The memory 258 stores instructions and data used, generated, or collected by the T-TRP 170. For example, the memory 258 could store software instructions or modules configured to implement some or all of the functionality and/or embodiments described herein and that are executed by the processor 260.

Although not illustrated, the processor 260 may form part of the transmitter 252 and/or part of the receiver 254. Also, although not illustrated, the processor 260 may implement the scheduler 253. Although not illustrated, the memory 258 may form part of the processor 260.

The processor 260, the scheduler 253, the processing components of the transmitter 252 and the processing components of the receiver 254 may each be implemented by the same, or different one of, one or more processors that are configured to execute instructions stored in a memory, e.g., in the memory 258. Alternatively, some or all of the processor 260, the scheduler 253, the processing components of the transmitter 252 and the processing components of the receiver 254 may be implemented using dedicated circuitry, such as a FPGA, a CPU, a GPU or an ASIC.

Notably, the NT-TRP 172 is illustrated as a drone only as an example, the NT-TRP 172 may be implemented in any suitable non-terrestrial form, such as high altitude platforms, satellite, high altitude platform as international mobile telecommunication base stations and unmanned aerial vehicles, which forms will be discussed hereinafter. Also, the NT-TRP 172 may be known by other names in some implementations, such as a non-terrestrial node, a non-terrestrial network device, or a non-terrestrial base station. The NT-TRP 172 includes a transmitter 272 and a receiver 274 coupled to one or more antennas 280. Only one antenna 280 is illustrated. One, some, or all of the antennas may alternatively be panels. The transmitter 272 and the receiver 274 may be integrated as a transceiver. The NT-TRP 172 further includes a processor 276 for performing operations including those related to: preparing a transmission for downlink transmission to the ED 110; processing an uplink transmission received from the ED 110; preparing a transmission for backhaul transmission to T-TRP 170; and processing a transmission received over backhaul from the T-TRP 170. Processing operations related to preparing a transmission for downlink or backhaul transmission may include operations such as encoding, modulating, precoding (e.g., MIMO precoding), transmit beamforming and generating symbols for transmission. Processing operations related to processing received transmissions in the uplink or over backhaul may include operations such as receive beamforming, demodulating received signals and decoding received symbols. In some embodiments, the processor 276 implements the transmit beamforming and/or receive beamforming based on beam direction information (e.g., BAI) received from the T-TRP 170. In some embodiments, the processor 276 may generate signaling, e.g., to configure one or more parameters of the ED 110. In some embodiments, the NT-TRP 172 implements physical layer processing but does not implement higher layer functions such as functions at the medium access control (MAC) layer or functions at the radio link control (RLC) layer. As this is only an example, more generally, the NT-TRP 172 may implement higher layer functions in addition to physical layer processing.

The NT-TRP 172 further includes a memory 278 for storing information and data. Although not illustrated, the processor 276 may form part of the transmitter 272 and/or part of the receiver 274. Although not illustrated, the memory 278 may form part of the processor 276.

The processor 276, the processing components of the transmitter 272 and the processing components of the receiver 274 may each be implemented by the same or different one or more processors that are configured to execute instructions stored in a memory, e.g., in the memory 278. Alternatively, some or all of the processor 276, the processing components of the transmitter 272 and the processing components of the receiver 274 may be implemented using dedicated circuitry, such as a programmed FPGA, a CPU, a GPU or an ASIC. In some embodiments, the NT-TRP 172 may actually be a plurality of NT-TRPs that are operating together to serve the ED 110, e.g., through coordinated multipoint transmissions.

The T-TRP 170, the NT-TRP 172, and/or the ED 110 may include other components, but these have been omitted for the sake of clarity.

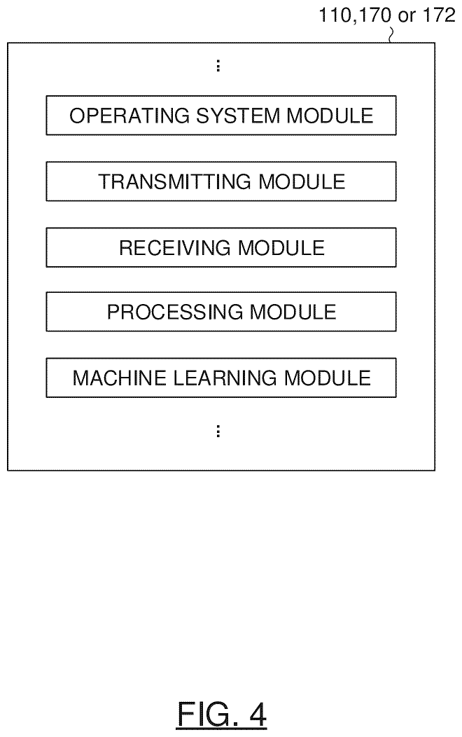

One or more steps of the embodiment methods provided herein may be performed by corresponding units or modules, according to FIG. 4. FIG. 4 illustrates units or modules in a device, such as in the ED 110, in the T-TRP 170 or in the NT-TRP 172. For example, a signal may be transmitted by a transmitting unit or by a transmitting module. A signal may be received by a receiving unit or by a receiving module. A signal may be processed by a processing unit or a processing module. Other steps may be performed by an artificial intelligence (AI) or machine learning (ML) module. The respective units or modules may be implemented using hardware, one or more components or devices that execute software, or a combination thereof. For instance, one or more of the units or modules may be an integrated circuit, such as a programmed FPGA, a CPU, a GPU or an ASIC. It will be appreciated that where the modules are implemented using software for execution by a processor, for example, the modules may be retrieved by a processor, in whole or part as needed, individually or together for processing, in single or multiple instances, and that the modules themselves may include instructions for further deployment and instantiation.

Additional details regarding the EDs 110, the T-TRP 170 and the NT-TRP 172 are known to those of skill in the art. As such, these details are omitted here.

An air interface generally includes a number of components and associated parameters that collectively specify how a transmission is to be sent and/or received over a wireless communications link between two or more communicating devices. For example, an air interface may include one or more components defining the waveform(s), frame structure(s), multiple access scheme(s), protocol(s), coding scheme(s) and/or modulation scheme(s) for conveying information (e.g., data) over a wireless communications link. The wireless communications link may support a link between a radio access network and user equipment (e.g., a “Uu” link), and/or the wireless communications link may support a link between device and device, such as between two user equipments (e.g., a “sidelink”), and/or the wireless communications link may support a link between a non-terrestrial (NT)-communication network and user equipment (UE). The following are some examples for the above components.

A waveform component may specify a shape and form of a signal being transmitted. Waveform options may include orthogonal multiple access waveforms and non-orthogonal multiple access waveforms. Non-limiting examples of such waveform options include Orthogonal Frequency Division Multiplexing (OFDM), Direct Fourier Transform spread OFDM (DFT-OFDM), Filtered OFDM (f-OFDM), Time windowing OFDM, Filter Bank Multicarrier (FBMC), Universal Filtered Multicarrier (UFMC), Generalized Frequency Division Multiplexing (GFDM), Wavelet Packet Modulation (WPM), Faster Than Nyquist (FTN) Waveform and low Peak to Average Power Ratio Waveform (low PAPR WF).

A frame structure component may specify a configuration of a frame or group of frames. The frame structure component may indicate one or more of a time, frequency, pilot signature, code or other parameter of the frame or group of frames. More details of frame structure will be discussed hereinafter.

A multiple access scheme component may specify multiple access technique options, including technologies defining how communicating devices share a common physical channel, such as: TDMA; FDMA; CDMA; SDMA; OFDMA; SC-FDMA; Low Density Signature Multicarrier CDMA (LDS-MC-CDMA); Non-Orthogonal Multiple Access (NOMA); Pattern Division Multiple Access (PDMA); Lattice Partition Multiple Access (LPMA); Resource Spread Multiple Access (RSMA); and Sparse Code Multiple Access (SCMA). Furthermore, multiple access technique options may include: scheduled access vs. non-scheduled access, also known as grant-free access; non-orthogonal multiple access vs. orthogonal multiple access, e.g., via a dedicated channel resource (e.g., no sharing between multiple communicating devices); contention-based shared channel resources vs. non-contention-based shared channel resources; and cognitive radio-based access.

A hybrid automatic repeat request (HARQ) protocol component may specify how a transmission and/or a re-transmission is to be made. Non-limiting examples of transmission and/or re-transmission mechanism options include those that specify a scheduled data pipe size, a signaling mechanism for transmission and/or re-transmission and a re-transmission mechanism.

A coding and modulation component may specify how information being transmitted may be encoded/decoded and modulated/demodulated for transmission/reception purposes. Coding may refer to methods of error detection and forward error correction. Non-limiting examples of coding options include turbo trellis codes, turbo product codes, fountain codes, low-density parity check codes and polar codes. Modulation may refer, simply, to the constellation (including, for example, the modulation technique and order), or more specifically to various types of advanced modulation methods such as hierarchical modulation and low PAPR modulation.

In some embodiments, the air interface may be a “one-size-fits-all” concept. For example, it may be that the components within the air interface cannot be changed or adapted once the air interface is defined. In some implementations, only limited parameters or modes of an air interface, such as a cyclic prefix (CP) length or a MIMO mode, can be configured. In some embodiments, an air interface design may provide a unified or flexible framework to support frequencies below known 6 GHz bands and frequencies beyond the 6 GHz bands (e.g., mmWave bands) for both licensed and unlicensed access. As an example, flexibility of a configurable air interface provided by a scalable numerology and symbol duration may allow for transmission parameter optimization for different spectrum bands and for different services/devices. As another example, a unified air interface may be self-contained in a frequency domain and a frequency domain self-contained design may support more flexible RAN slicing through channel resource sharing between different services in both frequency and time.

A frame structure is a feature of the wireless communication physical layer that defines a time domain signal transmission structure to, e.g., allow for timing reference and timing alignment of basic time domain transmission units. Wireless communication between communicating devices may occur on time-frequency resources governed by a frame structure. The frame structure may, sometimes, instead be called a radio frame structure.

Depending upon the frame structure and/or configuration of frames in the frame structure, frequency division duplex (FDD) and/or time-division duplex (TDD) and/or full duplex (FD) communication may be possible. FDD communication is when transmissions in different directions (e.g., uplink vs. downlink) occur in different frequency bands. TDD communication is when transmissions in different directions (e.g., uplink vs. downlink) occur over different time durations. FD communication is when transmission and reception occur on the same time-frequency resource, i.e., a device can both transmit and receive on the same frequency resource contemporaneously.

One example of a frame structure is a frame structure, specified for use in the known long-term evolution (LTE) cellular systems, having the following specifications: each frame is 10 ms in duration; each frame has 10 subframes, which subframes are each 1 ms in duration; each subframe includes two slots, each of which slots is 0.5 ms in duration; each slot is for the transmission of seven OFDM symbols (assuming normal CP); each OFDM symbol has a symbol duration and a particular bandwidth (or partial bandwidth or bandwidth partition) related to the number of subcarriers and subcarrier spacing; the frame structure is based on OFDM waveform parameters such as subcarrier spacing and CP length (where the CP has a fixed length or limited length options); and the switching gap between uplink and downlink in TDD is specified as the integer time of OFDM symbol duration.

Another example of a frame structure is a frame structure, specified for use in the known new radio (NR) cellular systems, having the following specifications: multiple subcarrier spacings are supported, each subcarrier spacing corresponding to a respective numerology; the frame structure depends on the numerology but, in any case, the frame length is set at 10 ms and each frame consists of ten subframes, each subframe of 1 ms duration; a slot is defined as 14 OFDM symbols; and slot length depends upon the numerology. For example, the NR frame structure for normal CP 15 kHz subcarrier spacing (“numerology 1”) and the NR frame structure for normal CP 30 kHz subcarrier spacing (“numerology 2”) are different. For 15 kHz subcarrier spacing, the slot length is 1 ms and, for 30 kHz subcarrier spacing, the slot length is 0.5 ms. The NR frame structure may have more flexibility than the LTE frame structure.

Another example of a frame structure is, e.g., for use in a 6G network or a later network. In a flexible frame structure, a symbol block may be defined to have a duration that is the minimum duration of time that may be scheduled in the flexible frame structure. A symbol block may be a unit of transmission having an optional redundancy portion (e.g., CP portion) and an information (e.g., data) portion. An OFDM symbol is an example of a symbol block. A symbol block may alternatively be called a symbol. Embodiments of flexible frame structures include different parameters that may be configurable, e.g., frame length, subframe length, symbol block length, etc. A non-exhaustive list of possible configurable parameters, in some embodiments of a flexible frame structure, includes: frame length; subframe duration; slot configuration; subcarrier spacing (SCS); flexible transmission duration of basic transmission unit; and flexible switch gap.

The frame length need not be limited to 10 ms and the frame length may be configurable and change over time. In some embodiments, each frame includes one or multiple downlink synchronization channels and/or one or multiple downlink broadcast channels and each synchronization channel and/or broadcast channel may be transmitted in a different direction by different beamforming. The frame length may be more than one possible value and configured based on the application scenario. For example, autonomous vehicles may require relatively fast initial access, in which case the frame length may be set to 5 ms for autonomous vehicle applications. As another example, smart meters on houses may not require fast initial access, in which case the frame length may be set as 20 ms for smart meter applications.

A subframe might or might not be defined in the flexible frame structure, depending upon the implementation. For example, a frame may be defined to include slots, but no subframes. In frames in which a subframe is defined, e.g., for time domain alignment, the duration of the subframe may be configurable. For example, a subframe may be configured to have a length of 0.1 ms or 0.2 ms or 0.5 ms or 1 ms or 2 ms or 5 ms, etc. In some embodiments, if a subframe is not needed in a particular scenario, then the subframe length may be defined to be the same as the frame length or not defined.

A slot might or might not be defined in the flexible frame structure, depending upon the implementation. In frames in which a slot is defined, then the definition of a slot (e.g., in time duration and/or in number of symbol blocks) may be configurable. In one embodiment, the slot configuration is common to all UEs 110 or a group of UEs 110. For this case, the slot configuration information may be transmitted to the UEs 110 in a broadcast channel or common control channel(s). In other embodiments, the slot configuration may be UE specific, in which case the slot configuration information may be transmitted in a UE-specific control channel. In some embodiments, the slot configuration signaling can be transmitted together with frame configuration signaling and/or subframe configuration signaling. In other embodiments, the slot configuration may be transmitted independently from the frame configuration signaling and/or subframe configuration signaling. In general, the slot configuration may be system common, base station common, UE group common or UE specific.

The SCS may range from 15 KHz to 480 KHz. The SCS may vary with the frequency of the spectrum and/or maximum UE speed to minimize the impact of Doppler shift and phase noise. In some examples, there may be separate transmission and reception frames and the SCS of symbols in the reception frame structure may be configured independently from the SCS of symbols in the transmission frame structure. The SCS in a reception frame may be different from the SCS in a transmission frame. In some examples, the SCS of each transmission frame may be half the SCS of each reception frame. If the SCS between a reception frame and a transmission frame is different, the difference does not necessarily have to scale by a factor of two, e.g., if more flexible symbol durations are implemented using inverse discrete Fourier transform (IDFT) instead of fast Fourier transform (FFT). Additional examples of frame structures can be used with different SCSs.

The basic transmission unit may be a symbol block (alternatively called a symbol), which, in general, includes a redundancy portion (referred to as the CP) and an information (e.g., data) portion. In some embodiments, the CP may be omitted from the symbol block. The CP length may be flexible and configurable. The CP length may be fixed within a frame or flexible within a frame and the CP length may possibly change from one frame to another, or from one group of frames to another group of frames, or from one subframe to another subframe, or from one slot to another slot, or dynamically from one scheduling to another scheduling. The information (e.g., data) portion may be flexible and configurable. Another possible parameter relating to a symbol block that may be defined is ratio of CP duration to information (e.g., data) duration. In some embodiments, the symbol block length may be adjusted according to: a channel condition (e.g., multi-path delay, Doppler); and/or a latency requirement; and/or an available time duration. As another example, a symbol block length may be adjusted to fit an available time duration in the frame.

A frame may include both a downlink portion, for downlink transmissions from a base station 170, and an uplink portion, for uplink transmissions from the UEs 110. A gap may be present between each uplink and downlink portion, which gap is referred to as a switching gap. The switching gap length (duration) may be configurable. A switching gap duration may be fixed within a frame or flexible within a frame and a switching gap duration may possibly change from one frame to another, or from one group of frames to another group of frames, or from one subframe to another subframe, or from one slot to another slot, or dynamically from one scheduling to another scheduling.

A device, such as a base station 170, may provide coverage over a cell. Wireless communication with the device may occur over one or more carrier frequencies. A carrier frequency will be referred to as a carrier. A carrier may alternatively be called a component carrier (CC). A carrier may be characterized by its bandwidth and a reference frequency, e.g., the center frequency, the lowest frequency or the highest frequency of the carrier. A carrier may be on a licensed spectrum or an unlicensed spectrum. Wireless communication with the device may also, or instead, occur over one or more bandwidth parts (BWPs). For example, a carrier may have one or more BWPs. More generally, wireless communication with the device may occur over spectrum. The spectrum may comprise one or more carriers and/or one or more BWPs.

A cell may include one or multiple downlink resources and, optionally, one or multiple uplink resources. A cell may include one or multiple uplink resources and, optionally, one or multiple downlink resources. A cell may include both one or multiple downlink resources and one or multiple uplink resources. As an example, a cell might only include one downlink carrier/BWP, or only include one uplink carrier/BWP, or include multiple downlink carriers/BWPs, or include multiple uplink carriers/BWPs, or include one downlink carrier/BWP and one uplink carrier/BWP, or include one downlink carrier/BWP and multiple uplink carriers/BWPs, or include multiple downlink carriers/BWPs and one uplink carrier/BWP, or include multiple downlink carriers/BWPs and multiple uplink carriers/BWPs. In some embodiments, a cell may, instead or additionally, include one or multiple sidelink resources, including sidelink transmitting and receiving resources.

A BWP is a set of contiguous or non-contiguous frequency subcarriers on a carrier, or a set of contiguous or non-contiguous frequency subcarriers on multiple carriers, or a set of non-contiguous or contiguous frequency subcarriers, which may have one or more carriers.

In some embodiments, a carrier may have one or more BWPs, e.g., a carrier may have a bandwidth of 20 MHz and consist of one BWP or a carrier may have a bandwidth of 80 MHz and consist of two adjacent contiguous BWPs, etc. In other embodiments, a BWP may have one or more carriers, e.g., a BWP may have a bandwidth of 40 MHz and consist of two adjacent contiguous carriers, where each carrier has a bandwidth of 20 MHz. In some embodiments, a BWP may comprise non-contiguous spectrum resources, which consists of multiple non-contiguous multiple carriers, where the first carrier of the non-contiguous multiple carriers may be in the mmW band, the second carrier may be in a low band (such as the 2 GHz band), the third carrier (if it exists) may be in THz band and the fourth carrier (if it exists) may be in visible light band. Resources in one carrier which belong to the BWP may be contiguous or non-contiguous. In some embodiments, a BWP has non-contiguous spectrum resources on one carrier.

Wireless communication may occur over an occupied bandwidth. The occupied bandwidth may be defined as the width of a frequency band such that, below the lower and above the upper frequency limits, the mean powers emitted are each equal to a specified percentage, β/2, of the total mean transmitted power, for example, the value of β/2 is taken as 0.5%.

The carrier, the BWP or the occupied bandwidth may be signaled by a network device (e.g., by a base station 170) dynamically, e.g., in physical layer control signaling such as the known downlink control channel (DCI), or semi-statically, e.g., in radio resource control (RRC) signaling or in signaling in the medium access control (MAC) layer, or be predefined based on the application scenario; or be determined by the UE 110 as a function of other parameters that are known by the UE 110, or may be fixed, e.g., by a standard.

UE position information is often used in cellular communication networks to improve various performance metrics for the network. Such performance metrics may, for example, include capacity, agility and efficiency. The improvement may be achieved when elements of the network exploit the position, the behavior, the mobility pattern, etc., of the UE in the context of a priori information describing a wireless environment in which the UE is operating.

A sensing system may be used to help gather UE pose information, including UE location in a global coordinate system, UE velocity and direction of movement in the global coordinate system, orientation information and the information about the wireless environment. “Location” is also known as “position” and these two terms may be used interchangeably herein. Examples of well-known sensing systems include RADAR (Radio Detection and Ranging) and LIDAR (Light Detection and Ranging). While the sensing system is typically separate from the communication system, it could be advantageous to gather the information using an integrated system, which reduces the hardware (and cost) in the system as well as the time, frequency or spatial resources needed to perform both functionalities. However, using the communication system hardware to perform sensing of UE pose and environment information is a highly challenging and open problem. The difficulty of the problem relates to factors such as the limited resolution of the communication system, the dynamicity of the environment, and the huge number of objects whose electromagnetic properties and position are to be estimated.

Accordingly, integrated sensing and communication (also known as integrated communication and sensing) is a desirable feature in existing and future communication systems.

Any or all of the EDs 110 and BS 170 may be sensing nodes in the system 100. Sensing nodes are network entities that perform sensing by transmitting and receiving sensing signals. Some sensing nodes are communication equipment that perform both communications and sensing. However, it is possible that some sensing nodes do not perform communications and are, instead, dedicated to sensing. The sensing agent 174 is an example of a sensing node that is dedicated to sensing. Unlike the EDs 110 and BS 170, the sensing agent 174 does not transmit or receive communication signals. However, the sensing agent 174 may communicate configuration information, sensing information, signaling information, or other information within the communication system 100. The sensing agent 174 may be in communication with the core network 130 to communicate information with the rest of the communication system 100. By way of example, the sensing agent 174 may determine the location of the ED 110a, and transmit this information to the base station 170a via the core network 130. Although only one sensing agent 174 is shown in FIG. 2, any number of sensing agents may be implemented in the communication system 100. In some embodiments, one or more sensing agents may be implemented at one or more of the RANs 120.

A sensing node may combine sensing-based techniques with reference signal-based techniques to enhance UE pose determination. This type of sensing node may also be known as a sensing management function (SMF). In some networks, the SMF may also be known as a location management function (LMF). The SMF may be implemented as a physically independent entity located at the core network 130 with connection to the multiple BSs 170. In other aspects of the present application, the SMF may be implemented as a logical entity co-located inside a BS 170 through logic carried out by the processor 260.

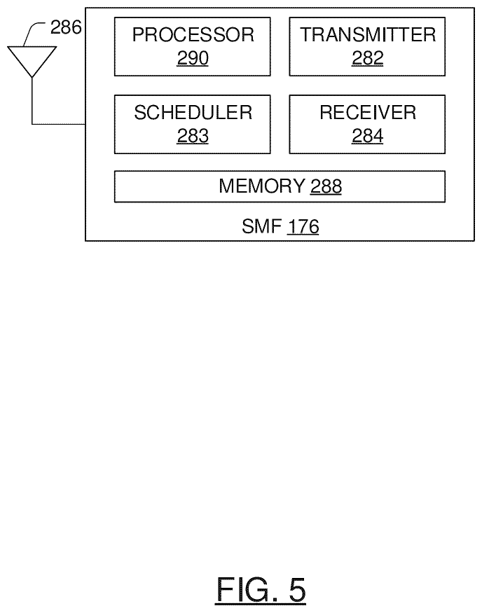

As shown in FIG. 5, an SMF 176, when implemented as a physically independent entity, includes at least one processor 290, at least one transmitter 282, at least one receiver 284, one or more antennas 286 and at least one memory 288. A transceiver, not shown, may be used instead of the transmitter 282 and the receiver 284. A scheduler 283 may be coupled to the processor 290. The scheduler 283 may be included within or operated separately from the SMF 176. The processor 290 implements various processing operations of the SMF 176, such as signal coding, data processing, power control, input/output processing or any other functionality. The processor 290 can also be configured to implement some or all of the functionality and/or embodiments described in more detail above. Each processor 290 includes any suitable processing or computing device configured to perform one or more operations. Each processor 290 could, for example, include a microprocessor, microcontroller, digital signal processor, field programmable gate array or application specific integrated circuit.

A reference signal-based pose determination technique belongs to an “active” pose estimation paradigm. In an active pose estimation paradigm, the enquirer of pose information (e.g., the UE 110) takes part in process of determining the pose of the enquirer. The enquirer may transmit or receive (or both) a signal specific to pose determination process. Positioning techniques based on a global navigation satellite system (GNSS) such as the known Global Positioning System (GPS) are other examples of the active pose estimation paradigm.

In contrast, a sensing technique, based on radar for example, may be considered as belonging to a “passive” pose determination paradigm. In a passive pose determination paradigm, the target is oblivious to the pose determination process.

By integrating sensing and communications in one system, the system need not operate according to only a single paradigm. Thus, the combination of sensing-based techniques and reference signal-based techniques can yield enhanced pose determination.

The enhanced pose determination may, for example, include obtaining UE channel sub-space information, which is particularly useful for UE channel reconstruction at the sensing node, especially for a beam-based operation and communication. The UE channel sub-space is a subset of the entire algebraic space, defined over the spatial domain, in which the entire channel from the TP to the UE lies. Accordingly, the UE channel sub-space defines the TP-to-UE channel with very high accuracy. The signals transmitted over other sub-spaces result in a negligible contribution to the UE channel. Knowledge of the UE channel sub-space helps to reduce the effort needed for channel measurement at the UE and channel reconstruction at the network-side. Therefore, the combination of sensing-based techniques and reference signal-based techniques may enable the UE channel reconstruction with much less overhead as compared to traditional methods. Sub-space information can also facilitate sub-space-based sensing to reduce sensing complexity and improve sensing accuracy.

In some embodiments of integrated sensing and communication, a same radio access technology (RAT) is used for sensing and communication. This avoids the need to multiplex two different RATs under one carrier spectrum, or necessitating two different carrier spectrums for the two different RATs.

In embodiments that integrate sensing and communication under one RAT, a first set of channels may be used to transmit a sensing signal and a second set of channels may be used to transmit a communications signal. In some embodiments, each channel in the first set of channels and each channel in the second set of channels is a logical channel, a transport channel or a physical channel.

At the physical layer, communication and sensing may be performed via separate physical channels. For example, a first physical downlink shared channel PDSCH-C is defined for data communication, while a second physical downlink shared channel PDSCH-S is defined for sensing. Similarly, separate physical uplink shared channels (PUSCH), PUSCH-C and PUSCH-S, could be defined for uplink communication and sensing.

In another example, the same PDSCH and PUSCH could be also used for both communication and sensing, with separate logical layer channels and/or transport layer channels defined for communication and sensing. Note also that control channel(s) and data channel(s) for sensing can have the same or different channel structure (format), occupy same or different frequency bands or bandwidth parts.

In a further example, a common physical downlink control channel (PDCCH) and a common physical uplink control channel (PUCCH) may be used to carry control information for both sensing and communication. Alternatively, separate physical layer control channels may be used to carry separate control information for communication and sensing. For example, PUCCH-S and PUCCH-C could be used for uplink control for sensing and communication respectively and PDCCH-S and PDCCH-C for downlink control for sensing and communication respectively.

Different combinations of shared and dedicated channels for sensing and communication, at each of the physical, transport, and logical layers, are possible.

The term RADAR originates from the phrase Radio Detection and Ranging; however, expressions with different forms of capitalization (e.g., Radar and radar) are equally valid and now more common. Radar is typically used for detecting a presence and a location of an object. A radar system radiates radio frequency energy and receives echoes of the energy reflected from one or more targets. The system determines the pose of a given target based on the echoes returned from the given target. The radiated energy can be in the form of an energy pulse or a continuous wave, which can be expressed or defined by a particular waveform. Examples of waveforms used in radar include frequency modulated continuous wave (FMCW) and ultra-wideband (UWB) waveforms.

Radar systems can be monostatic, bi-static or multi-static. In a monostatic radar system, the radar signal transmitter and receiver are co-located, such as being integrated in a transceiver. In a bi-static radar system, the transmitter and receiver are spatially separated, and the distance of separation is comparable to, or larger than, the expected target distance (often referred to as the range). In a multi-static radar system, two or more radar components are spatially diverse but with a shared area of coverage. A multi-static radar is also referred to as a multisite or netted radar.

Terrestrial radar applications encounter challenges such as multipath propagation and shadowing impairments. Another challenge is the problem of identifiability because terrestrial targets have similar physical attributes. Integrating sensing into a communication system is likely to suffer from these same challenges, and more.

Communication nodes can be either half-duplex or full-duplex. A half-duplex node cannot both transmit and receive using the same physical resources (time, frequency, etc.); conversely, a full-duplex node can transmit and receive using the same physical resources. Existing commercial wireless communications networks are all half-duplex. Even if full-duplex communications networks become practical in the future, it is expected that at least some of the nodes in the network will still be half-duplex nodes because half-duplex devices are less complex, and have lower cost and lower power consumption. In particular, full-duplex implementation is more challenging at higher frequencies (e.g., in millimeter wave bands) and very challenging for small and low-cost devices, such as femtocell base stations and UEs.

The limitation of half-duplex nodes in the communications network presents further challenges toward integrating sensing and communications into the devices and systems of the communications network. For example, both half-duplex and full-duplex nodes can perform bi-static or multi-static sensing, but monostatic sensing typically requires the sensing node have full-duplex capability. A half-duplex node may perform monostatic sensing with certain limitations, such as in a pulsed radar with a specific duty cycle and ranging capability.

Properties of a sensing signal, or a signal used for both sensing and communication, include the waveform of the signal and the frame structure of the signal. The frame structure defines the time-domain boundaries of the signal. The waveform describes the shape of the signal as a function of time and frequency. Examples of waveforms that can be used for a sensing signal include ultra-wide band (UWB) pulse, Frequency-Modulated Continuous Wave (FMCW) or “chirp”, orthogonal frequency-division multiplexing (OFDM), cyclic prefix (CP)-OFDM, and Discrete Fourier Transform spread (DFT-s)-OFDM.

In an embodiment, the sensing signal is a linear chirp signal with bandwidth B and time duration T. Such a linear chirp signal is generally known from its use in FMCW radar systems. A linear chirp signal is defined by an increase in frequency from an initial frequency, f_{chirp0}, at an initial time, t_{chirp0}, to a final frequency, f_{chirp1}, at a final time, t_{chirp1} where the relation between the frequency (f) and time (t) can be expressed as a linear relation of f−f_{chirp0}=α(t−t_{chirp0}), where

$$α = \frac{{f}_{chirp 1} - {f}_{chirp 0}}{{t}_{chirp 1} - {t}_{chirp 0}}$$

is defined as the chirp slope. The bandwidth of the linear chirp signal may be defined as B=f_{chirp1}−f_{chirp0} and the time duration of the linear chirp signal may be defined as T=t_{chirp1}−t_{chirp0}. Such linear chirp signal can be presented as e^{jπαt}^{²} in the baseband representation.

Precoding, as used herein, may refer to any coding operation(s) or modulation(s) that transform an input signal into an output signal. Precoding may be performed in different domains and typically transforms the input signal in a first domain to an output signal in a second domain. Precoding may include linear operations.

A terrestrial communication system may also be referred to as a land-based or ground-based communication system, although a terrestrial communication system can also, or instead, be implemented on or in water. The non-terrestrial communication system may bridge coverage gaps in underserved areas by extending the coverage of cellular networks through the use of non-terrestrial nodes, which will be key to establishing global, seamless coverage and providing mobile broadband services to unserved/underserved regions. In the current case, it is hardly possible to implement terrestrial access-points/base-stations infrastructure in areas like oceans, mountains, forests, or other remote areas.

The terrestrial communication system may be a wireless communications system using 5G technology and/or later generation wireless technology (e.g., 6G or later). In some examples, the terrestrial communication system may also accommodate some legacy wireless technologies (e.g., 3G or 4G wireless technology). The non-terrestrial communication system may be a communications system using satellite constellations, like conventional Geo-Stationary Orbit (GEO) satellites, which utilize broadcast public/popular contents to a local server. The non-terrestrial communication system may be a communications system using low earth orbit (LEO) satellites, which are known to establish a better balance between large coverage area and propagation path-loss/delay. The non-terrestrial communication system may be a communications system using stabilized satellites in very low earth orbits (VLEO) technologies, thereby substantially reducing the costs for launching satellites to lower orbits. The non-terrestrial communication system may be a communications system using high altitude platforms (HAPs), which are known to provide a low path-loss air interface for the users with limited power budget. The non-terrestrial communication system may be a communications system using Unmanned Aerial Vehicles (UAVs) (or unmanned aerial system, “UAS”) achieving a dense deployment, since their coverage can be limited to a local area, such as airborne, balloon, quadcopter, drones, etc. In some examples, GEO satellites, LEO satellites, UAVs, HAPs and VLEOs may be horizontal and two-dimensional. In some examples, UAVs, HAPs and VLEOs may be coupled to integrate satellite communications to cellular networks. Emerging 3D vertical networks consist of many moving (other than geostationary satellites) and high altitude access points such as UAVs, HAPs and VLEOs.

MIMO technology allows an antenna array of multiple antennas to perform signal transmissions and receptions to meet high transmission rate requirements. The ED 110 and the T-TRP 170 and/or the NT-TRP may use MIMO to communicate using wireless resource blocks. MIMO utilizes multiple antennas at the transmitter to transmit wireless resource blocks over parallel wireless signals. It follows that multiple antennas may be utilized at the receiver. MIMO may beamform parallel wireless signals for reliable multipath transmission of a wireless resource block. MIMO may bond parallel wireless signals that transport different data to increase the data rate of the wireless resource block.

In recent years, a MIMO (large-scale MIMO) wireless communication system with the T-TRP 170 and/or the NT-TRP 172 configured with a large number of antennas has gained wide attention from academia and industry. In the large-scale MIMO system, the T-TRP 170, and/or the NT-TRP 172, is generally configured with more than ten antenna units (see antennas 256 and antennas 280 in FIG. 3). The T-TRP 170, and/or the NT-TRP 172, is generally operable to serve dozens (such as 40) of EDs 110. A large number of antenna units of the T-TRP 170 and the NT-TRP 172 can greatly increase the degree of spatial freedom of wireless communication, greatly improve the transmission rate, spectral efficiency and power efficiency, and, to a large extent, reduce interference between cells. The increase of the number of antennas allows for each antenna unit to be made in a smaller size with a lower cost. Using the degree of spatial freedom provided by the large-scale antenna units, the T-TRP 170 and the NT-TRP 172 of each cell can communicate with many EDs 110 in the cell on the same time-frequency resource at the same time, thus greatly increasing the spectral efficiency. A large number of antenna units of the T-TRP 170 and/or the NT-TRP 172 also enable each user to have better spatial directivity for uplink and downlink transmission, so that the transmitting power of the T-TRP 170 and/or the NT-TRP 172 and an ED 110 is reduced and the power efficiency is correspondingly increased. When the antenna number of the T-TRP 170 and/or the NT-TRP 172 is sufficiently large, random channels between each ED 110 and the T-TRP 170 and/or the NT-TRP 172 can approach orthogonality such that interference between cells and users and the effect of noise can be reduced. The plurality of advantages described hereinbefore enable large-scale MIMO to have a magnificent application prospect.

A MIMO system may include a receiver connected to a receive (Rx) antenna, a transmitter connected to transmit (Tx) antenna and a signal processor connected to the transmitter and the receiver. Each of the Rx antenna and the Tx antenna may include a plurality of antennas. For instance, the Rx antenna may have a uniform linear array (ULA) antenna, in which the plurality of antennas are arranged in line at even intervals. When a radio frequency (RF) signal is transmitted through the Tx antenna, the Rx antenna may receive a signal reflected and returned from a forward target.

A non-exhaustive list of possible unit or possible configurable parameters or in some embodiments of a MIMO system include: a panel; and a beam.

A panel is a unit of an antenna group, or antenna array, or antenna sub-array, which unit can control a Tx beam or a Rx beam independently.

A beam may be formed by performing amplitude and/or phase weighting on data transmitted or received by at least one antenna port. A beam may be formed by using another method, for example, adjusting a related parameter of an antenna unit. The beam may include a Tx beam and/or a Rx beam. The transmit beam indicates distribution of signal strength formed in different directions in space after a signal is transmitted through an antenna. The receive beam indicates distribution of signal strength that is of a wireless signal received from an antenna and that is in different directions in space. Beam information may include a beam identifier, or an antenna port(s) identifier, or a channel state information reference signal (CSI-RS) resource identifier, or an SSB resource identifier, or a sounding reference signal (SRS) resource identifier, or other reference signal resource identifier.

In a conventional terrestrial continuous data reception scheme, multiple parallel HARQ processes are dimensioned to match the round-trip time of the communication system. This approach may be regarded as delay intolerant. When a communication system has a large propagation delay, such as in a non-terrestrial communication link, the UE may experience non-continuous data reception if its soft buffer is insufficiently-sized.

An existing example of delay-tolerant networking is the Bundle Protocol, described by the Internet Engineering Task Force in RFC 5050, which is available at datatracker.ietf.org/doc/html/rfc5050. The Bundle Protocol may be shown to rely upon the Store-Carry-Forward concept to incrementally send packets.

Aspects of the present application relate to a Selective Retransmission Protocol, a delay-tolerant protocol for non-terrestrial communications.

In contrast to the Bundle Protocol, which is defined above the Internet Protocol layer, aspects of the present application relate to a Selective Retransmission Request (SeRQ) of Transport Blocks (TBs).

In overview, in aspects of the SeRQ protocol proposed herein, a UE may group Retransmission Request (RTQ) feedback information bits for a plurality of transport blocks (TBs). Upon receipt of a plurality of TBs in a given window, for every TB that was not decoded correctly by the UE, the UE may generate an RTQ feedback information bit whose value is set to indicate a respective retransmission request, such as a “1.” For every TB that was decoded correctly by the UE, the UE may generate an RTQ feedback information bit whose value is set to indicate a respective no retransmission request, such as a “0.” In some embodiments, different values or combinations of values may be chosen to convey a desired indication. A window may be defined as a set of PDSCH reception occasions.

The RTQ feedback information may be understood to indicate, to the NT-TRP 172, which TBs, among the plurality of TBs in the window, were not decoded properly. UEs may generate RTQ feedback information bits for a group of TBs. The group of TBs may be TBs that have been received during a single window or TBs that have been received during multiple, distinct windows. The generation, by the UEs, of the RTQ feedback information bits for a group of TBs may be encoded based on, e.g., source coding, codebooks, binomial coefficients, etc. An RTQ feedback information codebook may be used, by a UE, to indicate, to the NT-TRP 172, which TBs, within a plurality of TBs, were not decoded properly. The RTQ feedback information codebook may, e.g., include a plurality of RTQ feedback information codebook tables for consecutive erroneous TBs (≥1).

The feedback, transmitted by the UE 110, may include an index to a selected RTQ feedback information codebook table and an index to a selected RTQ feedback information codebook entry within the selected RTQ feedback information codebook table. The RTQ feedback information codebook may be formally defined as a table of entries that encodes contiguous TB positions in a given window and associates an entry with a corresponding set of contiguous TB positions. RTQ feedback information codebooks may be indexed based on the number of contiguous TBs.

Upon generating RTQ feedback information bits, the UE may include RTQ feedback information bits in UCI. The UE may include, in the UCI, feedback for one or more RTQ groups in relation to one or more windows. The UCI may include RTQ feedback information bits for a given window indexed by a Window ID. RTQ feedback information may be expected to include one of: a code corresponding to a symbol of in a source coding scheme; an index of a binomial coefficient matching with erroneous TB positions; or an index of a given RTQ codebook in an RTQ codebook table in combination with an index of an RTQ codepoint in the given RTQ codebook.

A Soft Buffer, at a UE, may be dimensioned to hold up to W*N*M packets at any given time, where W is representative of a number of windows, N is representative of a number of TBs per window and M is representative of a maximum TB size.

Each TB may carry a header that indicates a Packet ID. The header may be defined as having B bits, where B≥1.

TBs for which retransmission has been requested may be referred to as RTQ-ed TBs. A UE 110 may transmit, to an NT-TRP 172, RTQ feedback regarding a given TB. Responsively, the NT-TRP 172 may transmit a redundancy version of the given RTQ-ed TB. Notably, the NT-TRP 172 may transmit the RTQ-ed TB in any window. Upon receipt of the RTQ-ed TB, the UE 110 may combine previously received bits of the given TB with the received redundancy version of the given TB. One example of combining relies on using so-called “soft-decision decoding” algorithms, where the output of a demodulator is a sequence of so-called “soft-bits” and where the soft-decision decoding algorithm makes use of a test to improve the probability of correctly decoding the given TB. The test may be implemented, for example, as a log-likelihood ratio (LLR) test. By way of the combining, as described hereinbefore, the UE 110 may decode the given TB.

A plurality of redundancy versions of a given TB may be jointly transmitted by an NT-TRP 172. A redundancy version of a given TB corresponds to a given number of information bits to which a given number of so-called “redundancy” bits have been added. The number of redundancy versions that are jointly transmitted may be determined, by the NT-TRP 172, on the basis of a plurality of factors. One such factor may, for example, be a Quality of Service (QoS) priority value associated with the given TB.

Arriving at definitions regarding windows for receiving a given number of TBs may start with an assumption that, in each time slot of a plurality of time slots, a single PDCCH carrying a single DCI format may be used to schedule a single PDSCH transmission carrying a single TB. However, it may be shown that this assumption can easily be extended to the case where a single PDSCH transmission carries a plurality of TBs, as illustrated in a dynamic length window scheme, described hereinafter.

Although aspects of the present application are presented hereinafter in the context of non-terrestrial or 6G communication systems, it notable that aspects of the present application may apply to scenarios distinct from non-terrestrial or 6G communication systems. Furthermore, it should be clear that the term “window” may be used inter-changeably with the term “partition.”

In aspects of the present application, the window has a fixed length. The length of the fixed-length window may be configured using higher-layer signaling (e.g., RRC signaling). Alternatively, the length of the fixed-length window may be configured on the basis of an established specification. The length of the fixed-length window may be communicated as a number of time slots. There are many alternatives for defining a time-slot unit. For several examples, a time-slot unit may be defined as: a subframe; a slot; a mini-slot; a group of OFDM symbols; or an OFDM symbol.

For every time slot, it may be assumed that each PDCCH independently schedules a PDSCH transmission in a given time slot. Aspects of the present application relate to the UE 110 generating an RTQ feedback information bit responsive to determining that a TB has been decoded incorrectly. Further aspects of the present application relate to the UE 110 generating an RTQ feedback information bit responsive to determining a failure to detect a PDCCH for a given time slot.

In another example, the fixed-length window is configured such that the UE 110 monitors, in only a subset of the time slots, for a PDCCH scheduling a PDSCH transmission. In the time slots that are not in the subset, the UE 110 does not monitor for a PDCCH scheduling a PDSCH transmission. Furthermore, there is no expectation that the UE 110 will generate an RTQ feedback information bit for the time slots that are not in the subset.

In aspects of the present application, the window has a variable length. An initial length of the variable-length window may be configured using higher-layer signaling (e.g., RRC signaling). Alternatively, an initial length of the variable-length window may be configured on the basis of an established specification. Assumptions may be made that a single PDCCH schedules a single PDSCH transmission and that a total number of PDSCH transmissions matches the length of the variable-length window.

The total number of PDSCH transmissions matching the length of the variable-length window allows the UE 110 to expect to receive a PDSCH in particular time slots. Advance information regarding the time slots in which to expect to receive a PDSCH may be shown to allow the UE 110 to decode a PDSCH transmission even if the corresponding PDCCH has not been detected. In a case wherein the last PDCCH has been missed, the UE 100 may lack information regarding when to transmit RTQ feedback information. This may be especially true if the last PDCCH is the PDCCH indicating a bundling of RTQs and a corresponding PUCCH resource.

In aspects of the present application, the window has a dynamic length, n (where n≥1). Assumptions may be made that there is only a single PDCCH in the window scheduling n PDSCH transmissions. The length of the window may be provided in a DCI format in terms of a number of PDSCH transmissions that are scheduled. The length of the window may be provided in higher-layer signaling (e.g., RRC signaling). The length of the window may be provided in some combination of DCI format and higher-layer signaling.

Aspects of the present application relate to generation of RTQ feedback information bits. Hereinafter, for simplicity, RTQ feedback information bits may be referenced as “RTQ feedback.” RTQ feedback may be generated based on source coding techniques that act to compress a decoding result into a “coded sequence.” An example source coding technique is known as Huffman coding. Alternatively, RTQ feedback may be generated based on further source coding techniques that act to compress a decoding result into a “coded sequence.” Examples of further source coding techniques include adaptive Huffman coding, Shannon coding, Fano-Elias coding, Lempel-Ziv coding and other source coding techniques collectively known as arithmetic coding. RTQ feedback may be generated using a binomial coefficient-based scheme. RTQ feedback may be generated using an RTQ codebook.

Without loss of generality: a dictionary is a set of input symbols, where each symbol comprises a number of bits, where each bit may represent a transport block's decoding status (e.g., correctly decoded or erroneously decoded). Similarly: a codebook is a set of code words, where each code word comprises a number of so-called “coded” bits, where the coded bits may represent the number of erroneously decoded transport blocks and/or the position of the erroneously decoded transport blocks. A given input symbol in a dictionary may be associated, e.g., in a one-to-one manner, with a given code word in a codebook. Other mapping or association mechanisms can be considered for linking input symbols in a dictionary with code words in a codebook.

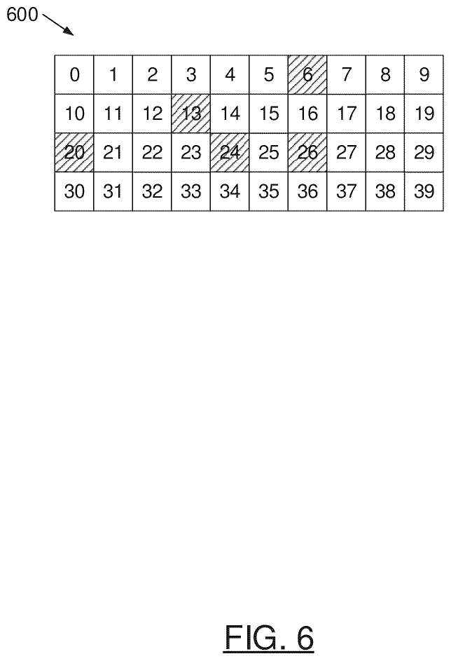

Starting with an assumption that the UE 110 has been configured to receive a window with length, N=40 TBs. All the TBs transmitted by the NT-TRP 172 may be received with a Block Error Rate (BLER) of 10%, i.e., there is a 10% probability that a given TB will be decoded erroneously. An example of a window 600 of 40 TBs is illustrated in FIG. 6. For RTQ feedback based on source coding techniques, the NT-TRP 172 and the UE 110 use the same value for the BLER to, thereby, ensure that both the NT-TRP 172 and the UE 110 use the same dictionary (i.e., the same set of input symbols) and the same codebook (i.e., the same set of output code words) when interpreting (at the NT-TRP 172 side) and generating (at the UE 110 side) the RTQ feedback. The BLER is used, by both the NT-TRP 172 and the UE 110, to generate the dictionary, based on symbols that comprise one or more bits. For a given symbol, each bit may be assigned a value of “0” if the TB at the corresponding position, in a group of TBs, was decoded correctly and may be assigned a value of “1” if the TB at the corresponding position, in the group of TBs, was decoded erroneously. For a given symbol, the probability of a bit being assigned a value of “0” is equal to 1-BLER (e.g., 90% when BLER=10%) and the probability of a bit being assigned a value of “1” is equal to the BLER (e.g., 10%, in this example).

In the example window 600 of FIG. 6, five TBs are illustrated as differentiated from the other 35 of the TBs. The differentiated TBs may be understood to be representative of TBs that have been decoded erroneously by a UE 110. Accordingly, these are the five TBs for which the UE 110 is to generate RTQ feedback. In aspects of the present application, the UE 110 may use coding methods to generate the RTQ feedback. For example, the UE 110 may use Huffman Codes. A source coding scheme is herein proposed wherein the bit value “0” is used to mark a position, in the window 600, for which no RTQ feedback is to be transmitted and wherein the bit value “1” is used to mark a position, in the window 600, for which RTQ feedback is to be transmitted. Using such a scheme, the window 600 of FIG. 6 may be represented as the following base sequence: 0000001000000100000010001010000000000000.

Notably, the proposed source coding scheme may be applied to an ACK/NACK-based HARQ procedure that may be found in current 5G NR systems, where a NACK bit is mapped to “1” and an ACK is mapped to “0.”

The proposed source coding scheme involves generating a dictionary of symbols to represent the base sequence. In one example dictionary, symbols are coded over four bits. Coding, with four-bit symbols, the base sequence representative of the window 600 of FIG. 6 leads to the following: 0000-0010-0000-0100-0000-1000-1010-0000-0000-0000.

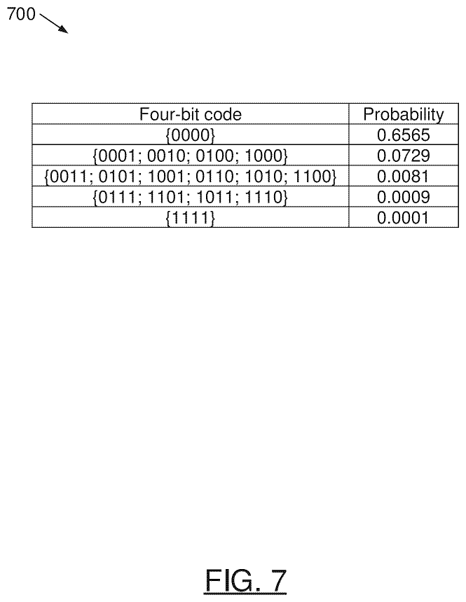

In view of a dictionary of four-bit symbols and the BLER, the probability of each symbol may be determined. A Huffman code probability table 700 is illustrated in FIG. 7.

There is a well-known algorithm for building a Huffman tree. The algorithm involves constructing a tree on the basis of the probability associated with each symbol in the dictionary. By operating according to the algorithm, a code may be generated for each symbol starting from the lowest probability symbols.

Using the probability table 700 of FIG. 7 and the algorithm for building the Huffman tree, a coded sequence may be obtained from the base sequence representative of the window 600 of FIG. 6. The coded sequence may appear as follows: 1-001-1-000-1-0101-0100100-1-1-1.

The coded sequence now comprises 23 bits. These 23 bits may form the RTQ feedback, generated by the UE 110 and included in the UCI. If, for one example, the UE 110 is transmitting a PUCCH carrying the UCI for the first four TBs (i.e., TBs {0, 1, 2, 3}) then the payload of the UCI contains the RTQ feedback corresponding to these TBs, i.e., RTQ=1. If, for another example, the UE 110 is transmitting a PUCCH carrying the UCI for the subsequent four TBs (i.e., TBs {4, 5, 6, 7}) then the payload of the UCI contains the RTQ feedback corresponding to these TBs, i.e., RTQ=001. In total, the UE 110 transmits 10 PUCCHs, with each PUCCH carrying a UCI with a Huffman code-generated RTQ feedback.

In some examples, when the UE 110 decodes all the TBs correctly and the Huffman code-generated RTQ feedback by the UE 110 is RTQ=1, the UE 110 does not transmit a PUCCH carrying the UCI for the four TBs (e.g., TBs {0, 1, 2, 3}) for which the corresponding RTQ feedback is RTQ=1. Instead the UE 110 discards the RTQ feedback corresponding to these TBs because none of these TBs require retransmission from the NT-TRP 172 and it helps the UE 110 reduce the number of UL transmissions to perform.

Aspects of the present application relate to generating RTQ feedback using a binomial coefficient-based scheme. Pascal's triangle is a known triangular array of the binomial coefficients. The binomial coefficients are the coefficients of the Integer terms in an expansion of (a+b)^{c}. For example, when c=5, the set of binomial coefficients is {1, 5, 10, 10, 5, 1}.

The example base sequence, 000000100000010000001000101000000000000000, representative of the window 600 of FIG. 6, as previously discussed, may be considered in the context of a distinct coding strategy.

It may be assumed that the window 600 of 40 TBs may be partitioned into partitions (or groups), where each partition of TBs has an integer number, n (where n≥1), of TBs. For each partition of TBs, there may be an integer number, k (where n≥k≥0), of erroneous TBs. Of course, RTQ feedback is not typically generated for the case wherein there are no erroneous TB, i.e., when k=0.

For example purposes, it may be assumed that the window 600 of 40 TBs may be divided into 10 partitions, where each partition of TBs has four TBs. In alternative embodiments, the window 600 of 40 TBs may be partitioned in other ways, such as: 20 partitions, where each partition of TBs has two TBs; eight partitions, where each partition of TBs has five TBs; five partitions, where each partition of TBs has eight TBs; four partitions, where each partition of TBs has ten TBs; and so on.

In the example illustrated in FIG. 6, the first partition the window 600 has no erroneous TBs. That is, in the window 600 of FIG. 6, there are no erroneous TBs among TBs {0, 1, 2, 3}. It follows that the UE 110 does not generate RTQ feedback for the first partition. Alternatively, the UE 110 may generate RTQ feedback entirely of “0” bits and then discard the RTQ feedback because only “0” bits are included.

In the example illustrated in FIG. 6, it is notable that there is a single erroneous TB in the second partition, which includes TBs {4, 5, 6, 7}. In particular, the UE 110 has identified the TB in the third position as not having been decoded correctly. Accordingly, k=1.

From Pascal's triangle, it is known that, when c=4, the set of binomial coefficients is {1, 4, 6, 4, 1}. When each partition has n=4 TBs, the set of binomial coefficients corresponds to k={0, 1, 2, 3, 4}. That is, the set of binomial coefficients corresponds to

$$\{ ( \begin{matrix}4 \\ 0\end{matrix} ) , ( \begin{matrix}4 \\ 1\end{matrix} ) , ( \begin{matrix}4 \\ 2\end{matrix} ) , ( \begin{matrix}4 \\ 3\end{matrix} ) , ( \begin{matrix}4 \\ 4\end{matrix} ) \} .$$

In general cases, the binomial coefficient,

$$( \begin{matrix}n \\ k\end{matrix} ) ,$$

may be encoded as m bits, where m is the lowest power of two that is larger than or equal to

$$( \begin{matrix}n \\ k\end{matrix} ) .$$

Accordingly, upon receiving m-bit RTQ feedback in a UCI, the NT-TRP 172 may recognize that an n-bit partition has been encoded to represent k erroneous TBs. Equivalently, we can say that m is the number of bits needed to encode the RTQ feedback.

In view of there being, in the second partition, a single erroneous TB, it may be considered that there are four possible locations for the single erroneous TB within a four-bit partition. It may also be taken into account that

$$( \begin{matrix}4 \\ 1\end{matrix} ) = 4$$

so that m=2. Accordingly, each one of four two-bit combinations may be mapped to represent each one of the four possible locations for a single erroneous TB in a four-bit partition. An RTQ feedback of “00” may be representative of the single erroneous TB occurring in the first position. An RTQ feedback of “01” may be representative of the single erroneous TB occurring in the second position. An RTQ feedback of “10” may be representative of the single erroneous TB occurring in the third position. An RTQ feedback of “11” may be representative of the single erroneous TB occurring in the fourth position. Of course, other mappings are contemplated.

According to aspects of the present application, upon identifying the TB in the third position as not having been decoded correctly, the UE 110 may generate the RTQ feedback, based on the mapping described hereinbefore, as “10.” Upon generating the RTQ feedback, the UE 110 may proceed to include the RTQ feedback in the UCI.

If, for example, the UE 110 is transmitting a PUCCH carrying the UCI for the second partition, then the payload of the UCI contains the RTQ feedback corresponding to the TBs of the second partition, i.e., the RTQ feedback is 10.

As mentioned generically hereinbefore, upon receiving two-bit RTQ feedback in a UCI, the NT-TRP 172 may recognize that a four-bit partition has been encoded to represent a single erroneous TB. However, it is also true that a two-bit RTQ feedback in a UCI may be representative of encoding of a four-bit partition to represent three erroneous TBs. In order to assist the NT-TRP 172, an additional bit corresponding to an “Upper/Lower” indication may be added by the UE 110 to differentiate

$$( \begin{matrix}4 \\ 1\end{matrix} ) = 4$$

from

$$( \begin{matrix}4 \\ 3\end{matrix} ) = 4.$$

Put another way, the additional bit corresponding to the “Upper/Lower” indication may be used to differentiate a number of bits for RTQ feedback selected based on a binomial coefficient in the first (lower) half of a given set of binomial coefficients (i.e., where

$$⌊ \frac{n}{2} ⌋ \geq k )$$

from number of bits for RTQ feedback selected based on a binomial coefficient in the second (upper) half of the given set of binomial coefficients (i.e., where

$$⌊ \frac{n}{2} ⌋ < k ) .$$

For the present example (the second partition of the window 600 in FIG. 6), an Upper/Lower bit with a value of “0” may accompany the RTQ feedback of “10.”

For the remaining partitions, the UE 110 applies the same procedure as described hereinbefore. For the partition including TBs {12, 13, 14, 15}, the corresponding UCI payload generated by the UE 110 may include an Upper/Lower bit with a value of “0” accompanying the RTQ feedback of “01.” For the partition including TBs {20, 21, 22, 23}, the corresponding UCI payload generated by the UE 110 may include an Upper/Lower bit with a value of “0” accompanying the RTQ feedback of “00.”

Notably, the seventh partition includes TBs {24, 25, 26, 27}. There are two erroneous TBs in the seventh partition, i.e., k=2.

In view of there being, in the seventh partition, two erroneous TBs, it may be considered that there are six possible patterns of two erroneous TBs within a four-bit partition. It may also be taken into account that

$$( \begin{matrix}4 \\ 2\end{matrix} ) = 6$$

so that m=3. Accordingly, six of the eight combinations of three bits may be mapped to represent each one of the six possible patterns of two erroneous TBs within a four-bit partition. An RTQ feedback of “001” may be representative of the two erroneous TBs occurring in the first position and the third position. Accordingly, for the partition including TBs {24, 25, 26, 27}, the corresponding UCI payload generated by the UE 110 may include an Upper/Lower bit with a value of “0” to accompany the RTQ feedback of “001.”

The mapping of the RTQ feedback “001” to two erroneous TBs occurring in the first position and the third position may be considered somewhat arbitrary. It follows that the mapping of particular patterns, of erroneous TBs among the TBs in a partition, to particular sets of bits is useful only when there is an identical mapping at the UE 110 and at the NT-TRP 172.

The UCI payload includes four binomial-coefficient-generated codes for a total of 13 bits, 010-000-001-0001, representing the 40 TBs resulting from the encoding. These 13 bits are the RTQ feedback generated by the UE 110 and then included in the UCI. In total, the UE 110 transmits four PUCCHs, with each PUCCH carrying a UCI with one of the four binomial-coefficient-generated codes.

In another example, a partition of four TBs contains three erroneous TBs, with an erroneous TB in the first position, the third position and the fourth position. Using the principles described hereinbefore, an Upper/Lower bit may be added with a value set as “0” if

$$k \leq \frac{n}{2}$$

and as “1” if

$$k > \frac{n}{2} .$$

The UE 110 may generate the RTQ feedback based on the binomial coefficient

$$( \begin{matrix}4 \\ 3\end{matrix} ) = 4.$$

For the present example, an Upper/Lower bit with a value of “1” may accompany the RTQ feedback of “01.”

In a further example, a partition of four TBs contains four erroneous TBs. Using the principles described hereinbefore, an Upper/Lower bit may be added with a value of “0” if

$$k \leq \frac{n}{2}$$

and with a value of “1” if

$$k > \frac{n}{2} .$$

The UE 110 may generate the RTQ feedback based on the binomial coefficient

$$( \begin{matrix}4 \\ 4\end{matrix} ) = 1.$$

For the present example, an Upper/Lower bit with a value of “1” may accompany the RTQ feedback of “1.”

Notably, for the above examples, it is possible for the UE 110 to generate only the RTQ feedback and to include the RTQ feedback in the UCI without including an “Upper/Lower” bit. This would further reduce the total number of bits that are included in the UCI. For instance, for the example of 40 TBs discussed hereinbefore, the resulting UCI payload devoted to the RTQ feedback may be reduced from 13 bits down to 9 bits. This reduction may be understood to come at the cost of possible misinterpretation of a representation of three erroneous TBs as a representation of a single erroneous TB, because the probability of there being three erroneous TBs in the same partition is significantly lower than the probability of there being a single erroneous TB in the same partition. Notably, it may be understood that the cost of possible misinterpretation of a binomial-coefficient-generated code increases with increasing partition size.

In some examples, there may be situations where there are two given positive integer numbers of erroneously decoded TBs, e.g., k₁ and k₂, where

$${k}_{1} < {k}_{2} \leq \frac{n}{2} ,$$

for which the number of bits needed to encode the RTQ feedback is equal, i.e.

$$⌈ {log}_{2} ( \begin{matrix}n \\ {k}_{1}\end{matrix} ) ⌉ = m and ⌈ {log}_{2} ( \begin{matrix}n \\ {k}_{2}\end{matrix} ) ⌉ = m ,$$

where ┌·┐ is the ceiling function. This would lead to situations where different numbers of erroneously decoded TBs correspond to the same code word length when using the binomial coefficient. In these situations, the UE 110 may use different code lengths in order to distinguish RTQ feedback bits generated based on k₁ and k₂. As an example, the UE 110 may use m₂=

$$⌈ {log}_{2} ( \begin{matrix}n \\ {k}_{2}\end{matrix} ) ⌉ + 1$$

to generate the RTQ feedback bits based on k₂, and the UE 110 may use m₁=

$$⌈ {log}_{2} ( \begin{matrix}n \\ {k}_{1}\end{matrix} ) ⌉$$

to generate the RTQ feedback bits based on k₁.

In some examples, there may be situations where there are two given positive integer numbers of erroneously decoded TBs, e.g., k₁ and k₂, where

$${k}_{1} > {k}_{2} \geq \frac{n}{2} ,$$

for which the number of bits needed to encode the RTQ feedback is equal, i.e.,

$$⌈ {log}_{2} ( \begin{matrix}n \\ {k}_{1}\end{matrix} ) ⌉ = m and ⌈ {log}_{2} ( \begin{matrix}n \\ {k}_{2}\end{matrix} ) ⌉ = m ,$$

where ┌·┐ is the ceiling function. This would lead to situations where different numbers of erroneously decoded TBs correspond to the same code word length when using the binomial coefficient. In these situations, the UE 110 may use different code lengths in order to distinguish RTQ feedback bits generated based on k₁ and k₂. As an example, the UE 110 may use m₂=

$$⌈ {log}_{2} ( \begin{matrix}n \\ {k}_{2}\end{matrix} ) ⌉ + 1$$

to generate the RTQ feedback bits based on k₂, and the UE 110 may use m₁=

$$⌈ {log}_{2} ( \begin{matrix}n \\ {k}_{1}\end{matrix} ) ⌉$$

to generate the RTQ feedback bits based on k₁.

In some examples, the codebook contains code words generated based on the binomial coefficient

$$( \begin{matrix}n \\ k\end{matrix} ) ,$$

where

$$( \begin{matrix}n \\ k\end{matrix} )$$

is lower than two to the power of m. In those examples, the UE 110 generates a number of code words that is equal to the binomial coefficient

$$( \begin{matrix}n \\ k\end{matrix} )$$

and the UE 110 generates the RTQ feedback bits based on the code words in the codebook. In some other examples, the UE 110 generates a number of code words that is equal to two to the power of m but some of the code words in the codebook are not used to generate the RTQ feedback bits.

Aspects of the present application relate to generating RTQ feedback using an RTQ feedback information codebook. For simplicity, an RTQ feedback information codebook may be referred to as an RTQ codebook.

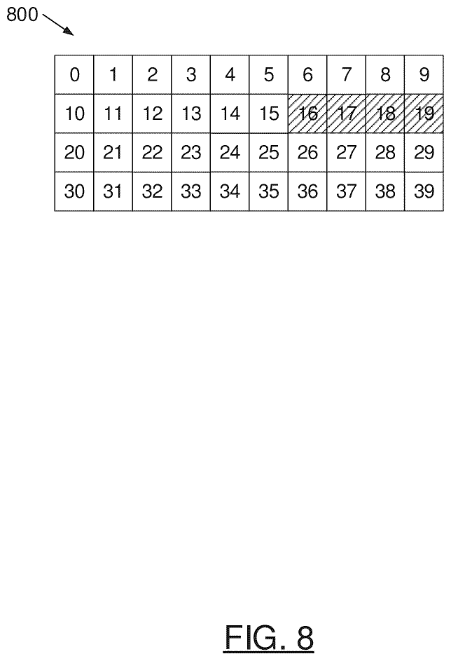

Starting with an assumption that the UE 110 has been configured to receive a window with length, N=40 TBs. All the TBs transmitted by the NT-TRP 172 may be received with a Block Error Rate (BLER) of 10%, i.e., there is a 10% probability that a given TB will be decoded erroneously. An example of a window 800 of 40 TBs is illustrated in FIG. 8.

In window 800 of FIG. 8, four contiguous TBs have been decoded erroneously and these are the four TBs for which the UE 110 is to generate an RTQ. In aspects of the present application, the UE 110 uses an algorithm based on using an RTQ codebook to generate the RTQ feedback.

A source coding scheme is herein proposed wherein the bit value “0” is used to mark a position, in the window 800, for which no RTQ is to be transmitted and wherein the bit value “1” is used to mark a position, in the window 800, for which an RTQ is to be transmitted. Using such a scheme, the window 800 of FIG. 8 may be represented as the following base sequence: 0000000000000000111100000000000000000000.

It has been noted hereinbefore that the proposed source coding scheme may be applied to an ACK/NACK-based HARQ procedure that may be found in current 5G NR systems, where a NACK bit is mapped to “1” and an ACK is mapped to “0.”

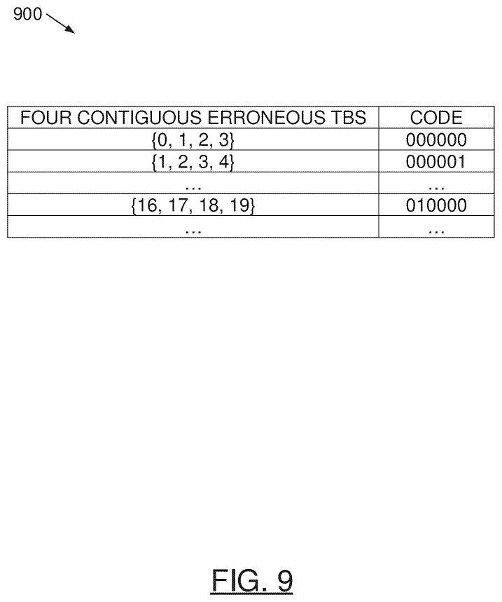

In the specific case wherein all erroneous TBs are contiguous, such as when the wireless channel is “bursty” (i.e., errors occurs in bursts), information specifying the starting TB may be sufficient to generate RTQ feedback. The UE 110 may generate entries for an RTQ codebook to be used for RTQ feedback, wherein each entry establishes a correspondence between a code and a given set of TB positions. An example RTQ codebook 900, for four contiguous erroneous TBs, is illustrated in FIG. 9.

A code obtained from the RTQ codebook 900 serves as the RTQ feedback generated by the UE 110 for including in the UCI. In addition to the code, the UE 110 may also feedback an index for the specific RTQ codebook to, thereby, assist the NT-TRP 172 in interpreting the code. The index of the RTQ codebook may effectively define a number of contiguous erroneous TBs that the UE failed to decode. In an example of the resulting RTQ feedback for the present example, an RTQ codebook index “0011” may accompany the code of “010000.”

The resulting RTQ portion of the UCI payload includes ten bits. These ten bits are the RTQ feedback generated by the UE 110 for including in the UCI. In total, the UE 110 transmits a single PUCCH carrying a UCI with RTQ codebook-based feedback.

In another example, the RTQ feedback generated by the UE 110, based on an RTQ codebook, may be generated by jointly encoding the first erroneous TB and the number of contiguous erroneous TBs. Assuming that S denotes an index for the first erroneous TB, N denotes the number of contiguous erroneous TBs and the UE 110 is configured to receive a window of 40 TBs, the RTQ feedback may be encoded as a Start Length Indicator Value (SLIV) obtained from SLIV=40*(N−1)+S. In aspects of the present application, the RTQ feedback may simply be implemented as an indication of an index for the first erroneous TB and an indication of the number of contiguous erroneous TBs.

For the window 800 of FIG. 8, wherein four contiguous erroneous TBs (N=4) start at the 16^{th} TB (S=16), the SLIV=40*(4−1)+16=40*3+16=136=0010001000. The UE 110 may include RTQ feedback “0010001000” in a UCI.

Aspects of the present application relate to generation of UCI for RTQ feedback. The UCI may be generated for RTQ feedback based on a Huffman coding strategy. The UCI may be generated for RTQ feedback based on a binomial coefficient-based scheme. The UCI may be generated for RTQ feedback based on an RTQ codebook.

Notably, every PUCCH transmission that carries UCI information bits is expected to be mapped to a number of PUCCH resources. The PUCCH resources may be configured by the NT-TRP 172 using, e.g., higher-layer signaling. Alternatively, the PUCCH resources may be dynamically indicated in the DCI format carried by a PDCCH transmission. Different numbers of UCI bits (typically upper-bounded and/or lower-bounded) may be mapped to the PUCCH resources. However, the number of PUCCH resources is expected to be fixed by the NT-TRP 172. The fixed number of PUCCH resources may be shown to allow the NT-TRP 172 to perform decoding of the PUCCH transmission.

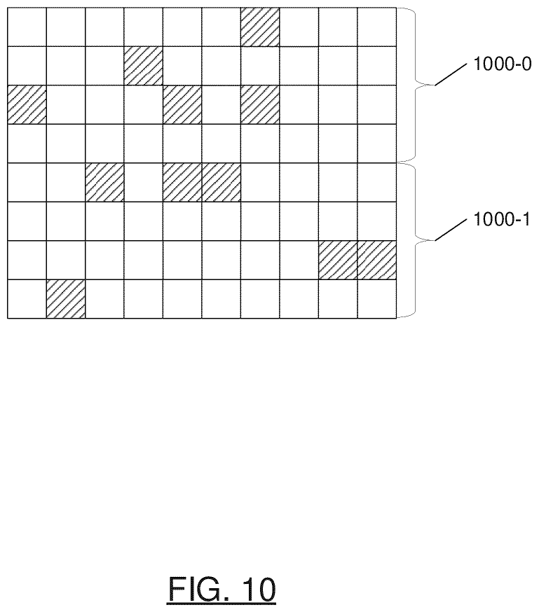

Starting with an assumption that the UE 110 has been configured to receive two windows, each window with length, N=40 TBs. The two windows may be understood to map to a so-called Soft Buffer at the UE 110. A pair of example windows is illustrated in FIG. 10. The pair of example windows includes a zeroth window (WINDOW0) 1000-0 of 40 TBs and a first window (WINDOW1) 1000-1 of 40 TBs.

For the purposes of aspects of the present application related to generation of UCI for RTQ feedback based on a Huffman coding strategy, it may be assumed that the UE 110 supports Huffman coding for generating RTQ feedback. The UE 110 may indicate, to the NT-TRP 172, support for Huffman coding for generating RTQ feedback. Consequently, the UE 110 may be configured, by the NT-TRP 172, to use Huffman Coding for generating RTQ feedback. For the present example, it may be assumed that the UE 110 has been configured to use a dictionary based on four-bit symbols (i.e., to represent four TBs). It may further be assumed that, for each four-bit symbol, there is a corresponding PUCCH transmission carrying the corresponding UCI.

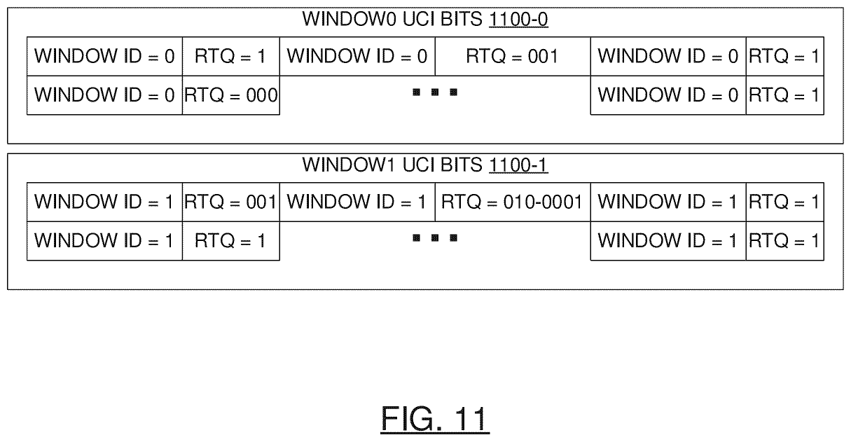

FIG. 11 illustrates a set of UCI bits 1100-0 for WINDOW0 and a set of UCI bits 1100-1 for WINDOW1. The set of UCI bits 1100-0 for WINDOW0 includes a plurality of sets of RTQ feedback information bits, {1, 001, 1, 000, . . . , 1}. The set of UCI bits 1100-1 for WINDOW1 includes a plurality of sets of RTQ feedback information bits, {001, 010-0001, 1, 1, . . . , 1}. FIG. 11 illustrates an optional arrangement wherein a single Window ID bit is associated with each set of RTQ feedback information bits. The single Window ID bit may be shown to allow the NT-TRP 172 to associate a particular window (i.e., WINDOW0 1000-0 or WINDOW1 1000-1 in FIG. 10) with each set of RTQ feedback information bits. The single Window ID bit may be shown to be especially helpful in situations wherein there are multiple UCI transmission opportunities.

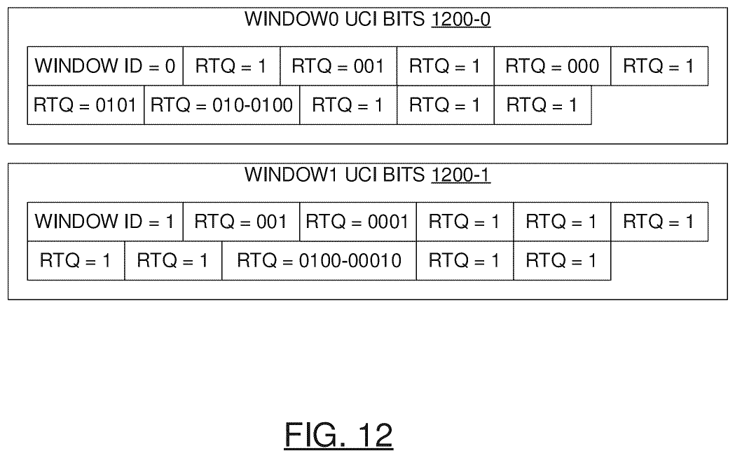

In another example, the UE 110 may include the sets of RTQ feedback information bits for all of the symbols in a given window, in a single UCI. The UE 110 may then transmit the single UCI in a corresponding PUCCH transmission. FIG. 12 illustrates a set of UCI bits 1200-0 for WINDOW0 and a set of UCI bits 1200-1 for WINDOW1. The set of UCI bits 1200-0 for WINDOW0 includes a single Window ID bit to identify the window to which the sets of RTQ feedback information bits relate. Similarly, the set of UCI bits 1200-1 for WINDOW1 includes a single Window ID bit to identify the window to which the sets of RTQ feedback information bits relate. The set of UCI bits 1200-0 for WINDOW0 includes a plurality of sets of RTQ feedback information bits, {1, 001, 1, 000, 1, 0101, 0010, 1, 1, 1}. The set of UCI bits 1200-1 for WINDOW1 includes a plurality of sets of RTQ feedback information bits, {001, 0001, 1, 1, 1, 1, 1, 0100-00010, 1, 1}.

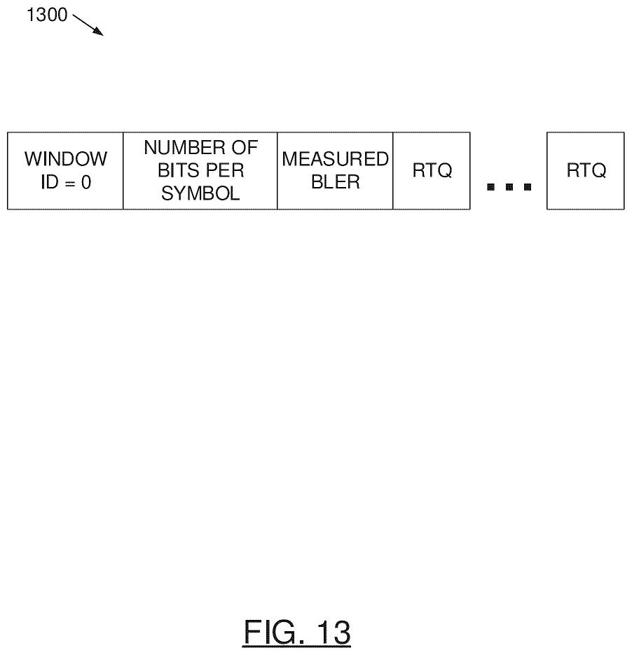

In another example, the UE 110 also generates RTQ feedback based on Huffman Coding. However, in a manner distinct to this example, the UE 110 may be configured to establish an updated dictionary of symbols. The updated Huffman Code dictionary may be established, by the UE 110, in a way that reflects a measured BLER rather than an expected BLER. Symbols may be represented, in the updated dictionary, over more than, or fewer than, four bits. In such a situation, it follows that UE 110 includes, in a UCI, information about the properties of the updated Huffman Code dictionary. Such property information is expected to allow the NT-TRP 172 to decode RTQ feedback received from the UE 110 and based on the updated Huffman Code dictionary. The property information may include, e.g., a number of symbols in the updated dictionary (where the dictionary is defined as the set of symbols that are used as input for Huffman Coding), a number of bits per symbol (where each symbol is coded over a certain number of bits) and the measured BLER. An example set of UCI bits 1300 is illustrated in FIG. 13 to include a Window ID, a number of bits per symbol, a measured BLER and a plurality of sets of RTQ feedback. Although it is not explicitly illustrated, each set of RTQ feedback should be understood to have been coded using the updated Huffman Code dictionary established by the UE 110 responsive to determining the measured BLER.

In another example, the NT-TRP 172 may configure the UE 110 with a higher-layer signaling (e.g., RRC signaling) parameter representative of an assumed BLER. For example, the higher-layer signaling parameter may be called “assumedBler” and may carry a single value, e.g., 0.1. The UE 110 may use the parameter assumedBler as a basis for defining a dictionary of input symbols. The behavior of the UE 110 may include using the dictionary of input symbols, defined based on the valued carried by the parameter assumedBler, to perform source coding, e.g., Huffman coding, to, thereby, generate RTQ feedback using methods described in the present application. The RTQ feedback may then be included as part of the UCI, as illustrated in FIG. 11.

In another example, the NT-TRP 172 may configure the UE 110 with a higher-layer signaling (e.g., RRC signaling) parameter representative of a number of bits per input symbol. For example, the higher-layer signaling parameter may be called “numberOfBitsPerlnputSymbol” and may carry a single value, e.g., 4. The UE 110 may use the parameter numberOfBitsPerlnputSymbol as a basis for defining a dictionary of input symbols. The behavior of the UE 110 may include using the dictionary of input symbols, defined based on the valued carried by the parameter numberOfBitsPerlnputSymbol, to perform source coding, e.g., Huffman coding, to, thereby, generate RTQ feedback using methods described in the present application. The RTQ feedback may then be included as part of the UCI, as illustrated in FIG. 11.

In another example, the NT-TRP 172 may configure the UE 110 with a higher-layer signaling (e.g., RRC signaling) parameter representative of an assumed BLER. For example, the higher-layer signaling parameter may be called “assumedBler” and may carry one or more values, e.g., {0.01, 0.05, 0.1, 0.2}. The UE 110 may use the parameter assumedBler as a basis for defining a dictionary of input symbols. The NT-TRP 172 may then transmit lower-layer signaling (e.g., a MAC-CE command) to, thereby, activate or deactivate certain values configured in the higher-layer signaling parameter assumedBler. An example of a MAC-CE command is given as follows:

| | | | | |
|---|---|---|---|---|
| p₃ = 1 | p₂ = 1 | p₁ = 0 | p₀ = 0 | Higher-layer signaling parameter = |
| | | | | assumedBler |

The MAC-CE command may be defined over a byte, i.e., eight bits. The first four bits may be used for a first field carrying a value that specifies the higher-layer signaling parameter for which the MAC-CE activation/deactivation command is meant. The remaining four bits may be used to activate or deactivate a given value of the higher-layer signaling parameter indicated in the first field. In the present example, the MAC-CE activation/deactivation command may be used, by the NT-TRP 172, to cause the UE 110 to activate certain ones of the four values of the higher-layer signaling parameter assumedBler. The values of assumedBler being activated in the present example are 0.1 and 0.2 because p₀ refers to the first value configured in assumedBler (i.e., 0.01), p₁ refers to the second value configured in assumedBler (i.e., 0.05), p₂ refers to the third value configured in assumedBler (i.e., 0.1) and p₃ refers to the fourth value configured in assumedBler (i.e., 0.2). For the i^{th} value, p₁, the value 1 means that the value of the corresponding higher-layer signaling parameter is to be activated, the value 0 means that the value of the corresponding higher-layer signaling parameter is to be deactivated. Upon receiving a PDSCH transmission carrying a MAC-CE command activating one or more values for assumedBler, there may be a time interval during which the UE 110 is to apply the content of the MAC-CE command before the NT-TRP 172 can consider that the MAC-CE command has been applied by the UE 110. The time interval may be configured in, for example, seconds, milli-seconds, micro-seconds, nano-seconds, etc.

In another example, the NT-TRP 172 may configure the UE 110 with a higher-layer signaling (e.g., RRC signaling) parameter representative of a number of bits per input symbol. For example, the higher-layer signaling parameter may be called “numberOfBitsPerlnputSymbol” and may carry one or more values, e.g., {4, 5, 10, 20}. The UE 110 may use the parameter numberOfBitsPerlnputSymbol as a basis for defining a dictionary of input symbols. The NT-TRP 172 may then transmit lower-layer signaling (e.g., a MAC-CE command) to, thereby, activate or deactivate certain values configured in the higher-layer signaling parameter numberOfBitsPerlnputSymbol. An example of a MAC-CE command is given as follows:

| | | | | |
|---|---|---|---|---|
| p₃ = 0 | p₂ = 1 | p₁ = 0 | p₀ = 1 | Higher-layer signaling parameter = |
| | | | | numberOfBitsPerInputSymbol |

The MAC-CE command may be defined over a byte, i.e., eight bits. The first four bits may be used for a first field carrying a value that specifies the higher-layer signaling parameter for which the MAC-CE activation/deactivation command is meant. The remaining four bits may be used to activate or deactivate a given value of the higher-layer signaling parameter indicated in the first field. In the present example, the MAC-CE activation/deactivation command may be used, by the NT-TRP 172, to cause the UE 110 to activate certain ones of the four values of the higher-layer signaling parameter numberOfBitsPerlnputSymbol. The values of numberOfBitsPerlnputSymbol being activated in the present example are 4 and 10, because p₀ refers to the first value configured in numberOfBitsPerlnputSymbol (i.e., 4), p₁ refers to the second value configured in numberOfBitsPerlnputSymbol (i.e., 5), p₂ refers to the third value configured in numberOfBitsPerlnputSymbol (i.e., 10) and p₃ refers to the fourth value configured in numberOfBitsPerlnputSymbol (i.e., 20). For the i^{th} value, p₁, the value 1 means the value of the corresponding higher-layer signaling parameter is to be activated, the value 0 means that the value of the corresponding higher-layer signaling parameter is to be deactivated. Upon receiving a PDSCH transmission carrying a MAC-CE command activating one or more values for numberOfBitsPerlnputSymbol, there may be a time interval during which the UE 110 is to apply the content of the MAC-CE command before the NT-TRP 172 can consider that the MAC-CE command has been applied by the UE 110. The time interval may be configured in, for example, seconds, milli-seconds, micro-seconds, nano-seconds, etc.

In another example, the NT-TRP 172 may configure the UE 110 with a higher-layer signaling (e.g., RRC signaling) parameter representative of an assumed BLER. For example, the higher-layer signaling parameter may be called “assumedBler” and may carry one or more values, e.g., {0.01, 0.05, 0.1, 0.2}. The UE 110 may use the parameter assumedBler as a basis for defining a dictionary of input symbols. The NT-TRP 172 may then transmit lower-layer signaling (e.g., a MAC-CE command) to, thereby, activate or deactivate certain values configured in the higher-layer signaling parameter assumedBler. After the one or more values of higher-layer signaling parameter assumedBler have been activated, the NT-TRP 172 may send a PDCCH transmission carrying DCI formatted with a field that may be used to indicate which one of the one or more values of assumedBler is to be used, by the UE 110, to define the dictionary of input symbols that may be used when generating the RTQ feedback. Based on an assumption that the lower-layer signaling has caused the UE 110 activate two values, the field may be a 1-bit field. A value of 0 in the field may be used to indicate the first of the two activated values of assumedBler and a value of 1 in the field may be used to indicate the second of the two activated values of assumedBler.

In another example, the NT-TRP 172 may configure the UE 110 with a higher-layer signaling (e.g., RRC signaling) parameter representative of a number of bits per input symbol. For example, the higher-layer signaling parameter may be called “numberOfBitsPerlnputSymbol” and may carry one or more values, e.g., {4, 5, 10, 20}. The UE 110 may use the parameter numberOfBitsPerlnputSymbol as a basis for defining a dictionary of input symbols. The NT-TRP 172 may then transmit lower-layer signaling (e.g., a MAC-CE command) to, thereby, activate or deactivate certain values configured in the higher-layer signaling parameter numberOfBitsPerlnputSymbol. After the one or more values of higher-layer signaling parameter numberOfBitsPerlnputSymbol have been activated, the NT-TRP 172 may send a PDCCH transmission carrying DCI formatted with a field that may be used to indicate which one of the one or more values of numberOfBitsPerlnputSymbol is to be used, by the UE 110, to define the dictionary of input symbols that may be used when generating the RTQ feedback. Based on an assumption that the lower-layer signaling has caused the UE 110 activate two values, the field may be a 1-bit field. A value of 0 in the field may be used to indicate the first of the two activated values of numberOfBitsPerlnputSymbol and a value of 1 in the field may be used to indicate the second of the two activated values of numberOfBitsPerInputSymbol.

For the purposes of aspects of the present application related to generation of UCI for RTQ feedback based on a binomial coefficient-based scheme, it may be assumed that the UE 110 supports binomial-coefficient-based RTQ feedback generation. The UE 110 may indicate, to the NT-TRP 172, support for binomial-coefficient-based RTQ feedback generation. Consequently, the UE 110 may be configured, by the NT-TRP 172, to use the binomial coefficient-based scheme for generating RTQ feedback. For the present example, it may be assumed that the UE 110 has been configured to transmit RTQ feedback for partitions of four PDSCH reception occasions, assuming a single TB per PDSCH reception occasion.

In the present example, the UE 110 generates a total of 10 UCIs, with each UCI carrying RTQ feedback for a given symbol. For each UCI, the UE 110 transmits a single PUCCH transmission carrying that UCI. The UCI bits may be expected to include at least the RTQ feedback. In addition, the UCI bits may also include an Upper/Lower bit to indicate, for the corresponding RTQ feedback, whether the number of RTQ-ed TBs is in the lower half (i.e., └n/2┘≥k) or in the upper half (i.e., └n/2┘<k). In addition, the UCI bits may also include a single Window ID bit to indicate a window to which the RTQ feedback corresponds. The single Window ID bit may be shown to allow the NT-TRP 172 to associate a particular window (i.e., WINDOW0 1000-0 or WINDOW1 1000-1 in FIG. 1) with each set of RTQ feedback information bits. The single Window ID bit may be shown to be especially helpful in situations wherein there are multiple UCI transmission opportunities.

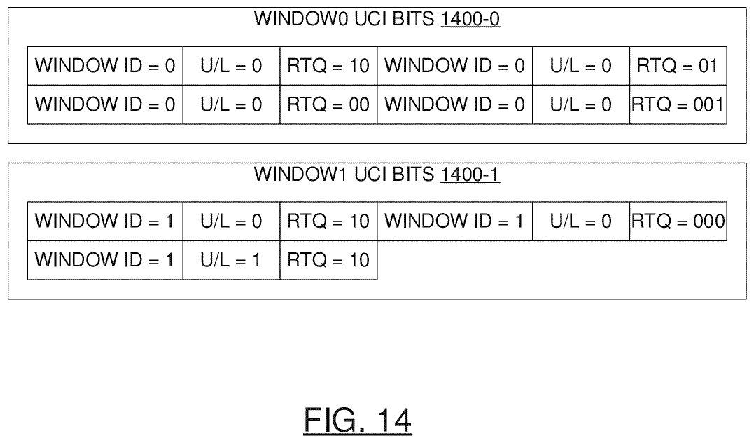

FIG. 14 illustrates a set of UCI bits 1400-0 for WINDOW0 1000-0 (see FIG. 10) and a set of UCI bits 1100-4 for WINDOW1 1000-1 (see FIG. 10). The set of UCI bits 1400-0 for WINDOW0 includes four sets of RTQ feedback information bits, {10, 01, 00, 001}. The set of UCI bits 1400-1 for WINDOW1 includes three sets of RTQ feedback information bits, {10, 000, 10}. FIG. 14 illustrates an optional arrangement wherein a single Window ID bit is associated with each set of RTQ feedback information bits. The single Window ID bit may be shown to allow the NT-TRP 172 to associate a particular window (i.e., WINDOW0 1000-0 or WINDOW1 1000-1 in FIG. 10) with each set of RTQ feedback information bits. The single Window ID bit may be shown to be especially helpful in situations wherein there are multiple UCI transmission opportunities. FIG. 14 also illustrates an optional arrangement wherein a single Upper/Lower (“U/L”) bit is associated with each set of RTQ feedback information bits. As discussed hereinbefore, the U/L bit may be used to differentiate a binomial coefficient selected from the first (lower) half of a given set of binomial coefficients (i.e., where

$$⌊ \frac{n}{2} ⌋ \geq k )$$

from a binomial coefficient selected from the second (upper) half of the given set of binomial coefficients (i.e., where

$$⌊ \frac{n}{2} ⌋ < k ) .$$

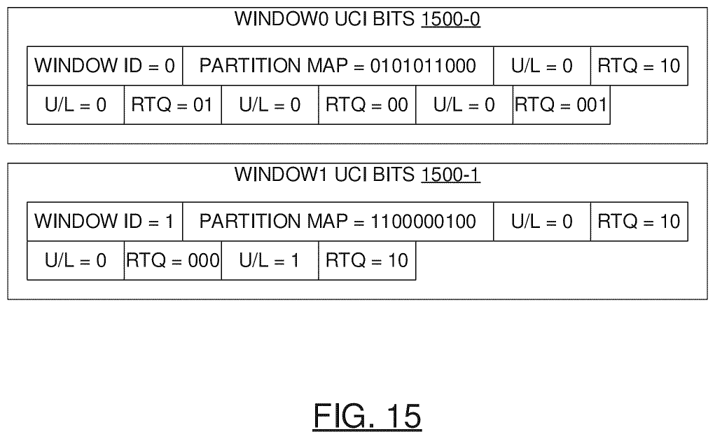

In another example, the UE 110 may include the sets of RTQ feedback information bits for all of the symbols in a given window, in a single UCI. The UE 110 may then transmit the single UCI in a corresponding PUCCH transmission. FIG. 15 illustrates a set of UCI bits 1500-0 for WINDOW0 and a set of UCI bits 1500-1 for WINDOW1. The set of UCI bits 1500-0 for WINDOW0 includes a single Window ID bit to identify the window to which the sets of RTQ feedback information bits relate. Similarly, the set of UCI bits 1500-1 for WINDOW1 includes a single Window ID bit to identify the window to which the sets of RTQ feedback information bits relate.

The set of UCI bits 1500-0 for WINDOW0 includes four sets of RTQ feedback information bits, {10, 01, 00, 001}. Each set among the four sets of RTQ feedback information bits may be associated with a U/L bit. The set of UCI bits 1500-1 for WINDOW1 includes three sets of RTQ feedback information bits, {10, 000, 10}. Each set among the three sets of RTQ feedback information bits may be associated with a U/L bit.

In addition, the set of UCI bits 1500-0 for WINDOW0 is illustrated as including a partition bitmap for WINDOW0. The partition bitmap has a number of bits corresponding to the number of partitions in WINDOW0. The partition bitmap includes a bit set to “1” corresponding to each of the four partitions in which erroneous TB are located. The rest of the bits in the partition bitmap are set to “0.” The set of UCI bits 1500-1 for WINDOW1 is illustrated as including a partition bitmap for WINDOW1. The partition bitmap has a number of bits corresponding to the number of partitions in WINDOW1. The partition bitmap includes a bit set to “1” corresponding to each of the three partitions in which erroneous TB are located. The rest of the bits in the partition bitmap are set to “0.” The partition bitmap may be shown to assist the NT-TRP 172 in interpreting the RTQ feedback correctly.

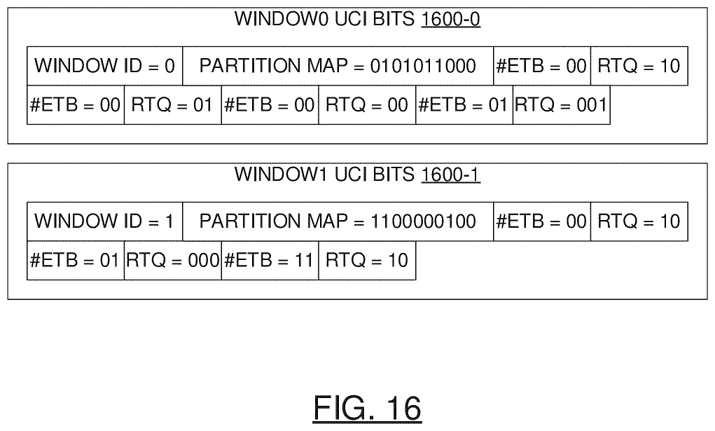

As an alternative to the set of UCI bits 1500-0 for WINDOW0 and the set of UCI bits 1500-1 for WINDOW1, illustrated in FIG. 15, FIG. 16 illustrates a set of UCI bits 1600-0 for WINDOW0 and a set of UCI bits 1600-1 for WINDOW1. The set of UCI bits 1600-0 for WINDOW0 in FIG. 16 has in common with the set of UCI bits 1500-0 for WINDOW0 in FIG. 15 the window ID and each of the four sets of RTQ feedback information bits. The set of UCI bits 1600-0 for WINDOW0 in FIG. 16 differs from the set of UCI bits 1500-0 for WINDOW0 in FIG. 15 in that, in place of the U/L bit associated with each of the four sets of RTQ feedback information bits (in FIG. 15), the set of UCI bits 1600-0 for WINDOW0 in FIG. 16 has a pair of bits to indicate a number of erroneous TBs (#ETB) for each of the four partitions in which erroneous TB are located. A similar replacement is made for the set of UCI bits 1600-1 for WINDOW1. The #ETB bits may take on one of four values, with “00” indicating one erroneous TB, “01” indicating two erroneous TBs, “10” indicating three erroneous TB and “11” indicating four erroneous TBs. This approach may be considered to have an advantage, in that the possibility of misinterpretation of the UCI is reduced by allowing the NT-TRP 172 to know, or derive, an exact length for each field within the UCI. For instance, the field for the Window ID, the field for the partition bitmap and the field for the #ETB may have fixed widths. When the fixed widths are known to the NT-TRP 172, the value carried in the partition bitmap field may be shown to allow the NT-TRP 172 to derive the number of #ETB fields and corresponding RTQ fields that are included in the UCI. The value carried in the #ETB field allows the NT-TRP 172 to derive the width of the subsequent RTQ field.

In some aspects of the present application, the set of UCI bits 1600-0 for WINDOW0 in FIG. 16 may also include a number of bits to indicate the number of TBs (#TB) in a given partition. As an example, the #TB bits may cover three bits and those three bits may take on one of eight values, with “000” indicating one TB in the partition, “001” indicating two TBs in the partition, “010” indicating three TBs in the partition, “011” indicating four TBs in the partition, “100” indicating five TBs in the partition, “101” indicating six TBs in the partition, “110” indicating seven TBs in the partition and “111” indicating eight TBs in the partition. The #TB bits may be appended prior to the #ETB bits or subsequent to the #ETB bits. This approach may be considered to have an advantage, in that the UE can use different partition sizes within the same window and encode the RTQ feedback bits in view of the number of TBs in the partition. This approach may also be considered to reduce the possibility of misinterpretation of the UCI, by allowing the NT-TRP 172 to know, or derive, an exact length for each field within the UCI. The value carried in the #TB and #ETB fields allow the NT-TRP 172 to derive the width of the subsequent RTQ field. Examples where #TB covers more than or fewer than three bits are also contemplated.

In some aspects of the present application, the NT-TRP 172 may configure the UE 110 with a higher-layer signaling (e.g., RRC signaling) parameter representative of a number of partitions. For example, the higher-layer signaling parameter may be called “numberofPartitions” and may carry a single value, e.g., 5. The UE 110 may use the parameter numberofPartitions to partition a given window of 40 TBs into five partitions, with eight TBs in each partition. The behavior of the UE 110 may include generating the RTQ feedback based on the binomial coefficient-based scheme for five partitions as configured by the higher-layer signaling parameter numberofPartitions.

In some aspects of the present application, the NT-TRP 172 may configure the UE 110 with a higher-layer signaling (e.g., RRC signaling) parameter representative of a number of TBs in each partition among a plurality of equally sized partitions. For example, the higher-layer signaling parameter may be called “numberofTBsinPartition” and may carry a single value, e.g., 5. The UE 110 may use the parameter numberofTBsinPartition to define a number of TBs for each partition into which a given window may be divided. For example, the UE 110 may partition a given window of 40 TBs into eight partitions, with five TBs in each partition. The behavior of the UE 110 may include generating the RTQ feedback based on the binomial coefficient-based scheme for eight partitions as configured by the higher-layer signaling parameter numberofPartitions.

In some aspects of the present application, the NT-TRP 172 may configure the UE 110 with a higher-layer signaling (e.g., RRC signaling) parameter representative of a number of partitions. For example, the higher-layer signaling parameter may be called “numberofPartitions” and may carry one or more values, e.g., {5, 10, 20, 40}. The UE 110 may use the parameter numberofPartitions to define a number of partitions into which a given window may be divided. In some embodiments, the NT-TRP 172 may configure the UE 110 with a higher-layer signaling (e.g. RRC) parameter numberofPartitions carrying one or more values e.g. {5, 10, 20, 40}, which the UE uses to define the number of partitions within a given window. The NT-TRP 172 may then transmit a lower-layer signaling (e.g., a MAC-CE command) to, thereby, activate or deactivate certain values configured in the higher-layer signaling parameter numberofPartitions. An example of a MAC-CE command is given as follows:

| | | | | |
|---|---|---|---|---|
| p₃ = 0 | p₂ = 0 | p₁ = 1 | p₀ = 1 | Higher-layer signaling parameter = |
| | | | | numberofPartitions |

The MAC-CE command may be defined over a byte, i.e., eight bits. The first four bits may be used for a first field carrying a value that specifies the higher-layer signaling parameter for which the MAC-CE activation/deactivation command is meant. The remaining four bits may be used to activate or deactivate a given value of the higher-layer signaling parameter indicated in the first field. In the present example, the MAC-CE activation/deactivation command is used, by the NT-TRP 172, to cause the UE 110 to activate certain ones of the four values of the higher-layer signaling parameter numberofPartitions. The values of numberofPartitions being activated in the present example are 5 and 10, because p₀ refers to the first value configured in numberofPartitions (i.e., 5), p₁ refers to the second value configured in numberofPartitions (i.e., 10), P₂ refers to the third value configured in numberofPartitions (i.e., 20) and p₃ refers to the fourth value configured in numberofPartitions (i.e., 40). For the i^{th} value, p₁, the field value 1 means the value of the corresponding higher-layer signaling parameter is being activated, the field value 0 means the value of the corresponding higher-layer signaling parameter is being deactivated. Upon receiving a PDSCH transmission carrying a MAC-CE command activating one or more values for numberofPartitions, there may be a time interval during which the UE 110 is to apply the content of the MAC-CE command before the NT-TRP 172 can consider that the MAC-CE command has been applied by the UE 110. The time interval may be configured in, for example, seconds, milli-seconds, micro-seconds, nano-seconds, etc.

In some aspects of the present application, the NT-TRP 172 may configure the UE 110 with a higher-layer signaling (e.g., RRC signaling) parameter representative of a number of TBs in each partition among a plurality of equally sized partitions. For example, the higher-layer signaling parameter may be called “numberofTBsinPartition” and may carry one or more values, e.g., {2, 3, 4, 5}. The UE 110 may use the parameter numberofTBsinPartition to define a number of TBs for each partition into which a given window may be divided. The NT-TRP 172 may then transmit a lower-layer signaling (e.g., a MAC-CE command) to, thereby, activate or deactivate certain values configured in the higher-layer signaling parameter numberofTBsinPartition. An example of a MAC-CE command is given as follows:

| | | | | |
|---|---|---|---|---|
| p₃ = 1 | p₂ = 1 | p₁ = 0 | p₀ = 0 | Higher-layer signaling parameter = |
| | | | | numberofTBsinPartition |

The MAC-CE command may be defined over a byte, i.e., eight bits. The first four bits may be used for a first field carrying a value that specifies the higher-layer signaling parameter for which the MAC-CE activation/deactivation command is meant. The remaining four bits may be used to activate or deactivate a given value of the higher-layer signaling parameter indicated in the first field. In the present example, the MAC-CE activation/deactivation command is used, by the NT-TRP 172, to cause the UE 110 to activate certain ones of the four values of the higher-layer signaling parameter numberofTBsinPartition. The values of numberofTBsinPartition being activated in the present example are 4 and 5, because p₀ refers to the first value configured in numberofTBsinPartition (i.e., 2), p₁ refers to the second value configured in numberofTBsinPartition (i.e., 3), p₂ refers to the third value configured in numberofTBsinPartition (i.e., 4) and p₃ refers to the fourth value configured in numberofTBsinPartition (i.e., 5). For the i^{th} value, p₁, the field value 1 means the value of the corresponding higher-layer signaling parameter is being activated, the field value 0 means the value of the corresponding higher-layer signaling parameter is being deactivated. Upon receiving a PDSCH transmission carrying a MAC-CE command activating one or more values for numberofTBsinPartition, there may be a time interval during which the UE 110 is to apply the content of the MAC-CE command before the NT-TRP 172 can consider that the MAC-CE command has been applied by the UE 110. The time interval may be configured in, for example, seconds, milli-seconds, micro-seconds, nano-seconds, etc.

For the purposes of aspects of the present application related to generation of UCI for RTQ feedback based on an RTQ codebook-based strategy, it may be assumed that the UE 110 supports RTQ codebook-based RTQ feedback generation. The UE 110 may indicate, to the NT-TRP 172, support for RTQ codebook-based RTQ feedback generation. Consequently, the UE 110 may be configured, by the NT-TRP 172, to use an RTQ codebook for generating RTQ feedback. For the present example, it may be assumed that the UE 110 has been configured to transmit RTQ feedback for partitions of four PDSCH reception occasions, assuming a single TB per PDSCH reception occasion.

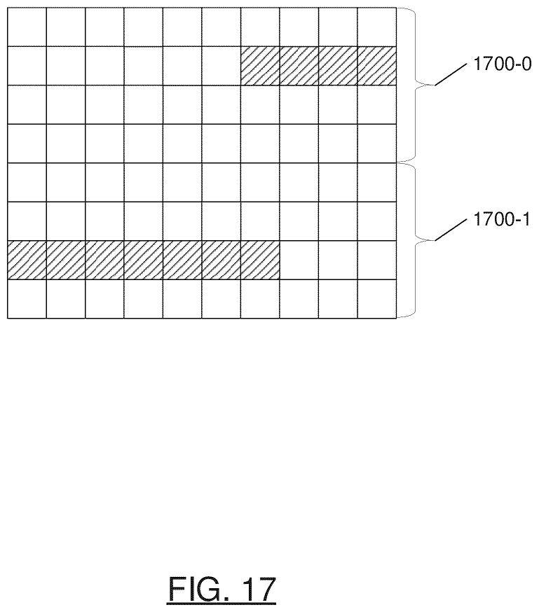

A pair of example windows is illustrated in FIG. 17. The pair of example windows includes a zeroth window (WINDOW0) 1000-0 of 40 TBs and a first window (WINDOW1) 1000-1 of 40 TBs.

In WINDOW0 1000-0 of FIG. 17, four contiguous TBs have been decoded erroneously and these are the four TBs for which the UE 110 is to generate an RTQ. In WINDOW1 1000-1 of FIG. 17, seven contiguous TBs have been decoded erroneously and these are the seven TBs for which the UE 110 is to generate an RTQ.

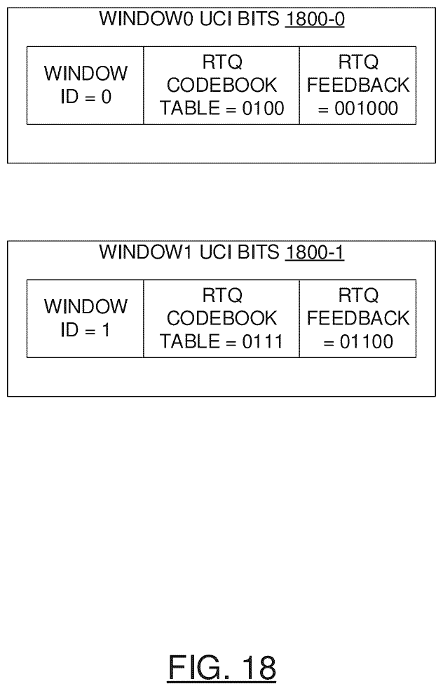

FIG. 18 illustrates a set of UCI bits 1800-0 for WINDOW0 1700-0 of FIG. 17 and a set of UCI bits 1800-1 for WINDOW1 1700-1 of FIG. 17.

The set of UCI bits 1800-0 for WINDOW0 1700-0 includes at least RTQ feedback information bits. The set of UCI bits 1800-1 for WINDOW0 1700-1 includes at least RTQ feedback information bits. In addition, the set of UCI bits 1800-0 for WINDOW0 1700-0 may also include an index of an RTQ Codebook for the RTQ feedback. In addition, the set of UCI bits 1800-1 for WINDOW1 1700-1 may also include an index of an RTQ Codebook for the RTQ feedback. In each case, the index of the RTQ Codebook may be understood to represent the number of RTQ-ed TBs. The index is 4 (represented as 0100) for WINDOW0 1700-0 and the index is 7 (represented as 0111) for WINDOW1 1700-1.

The set of UCI bits 1800-0 for WINDOW0 1700-0 includes a single Window ID bit to identify the window to which the sets of RTQ feedback information bits relate. Similarly, the set of UCI bits 1800-1 for WINDOW1 1700-1 includes a single Window ID bit to identify the window to which the sets of RTQ feedback information bits relate.

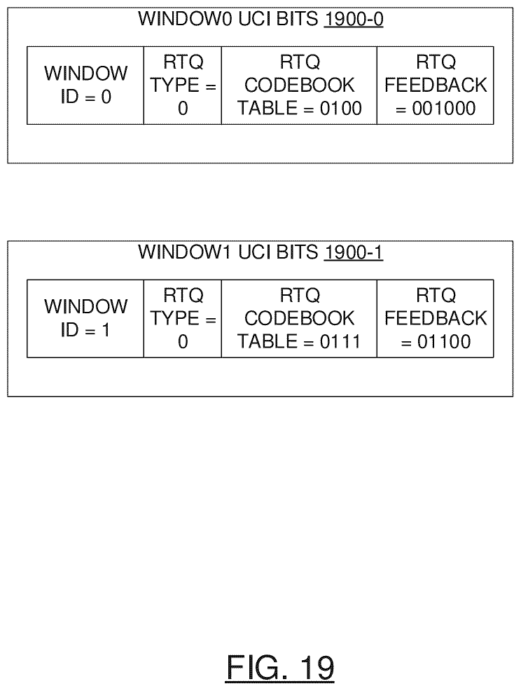

As an alternative to the set of UCI bits 1800-0 for WINDOW0 1700-0 and the set of UCI bits 1800-1 for WINDOW1 1700-1, illustrated in FIG. 18, FIG. 19 illustrates a set of UCI bits 1900-0 for WINDOW0 1700-0 and a set of UCI bits 1900-1 for WINDOW1 1700-1. The set of UCI bits 1900-0 for WINDOW0 in FIG. 19 has in common with the set of UCI bits 1800-0 for WINDOW0 in FIG. 18 the window ID, the index for RTQ codebook table and RTQ feedback information bits. The set of UCI bits 1900-0 for WINDOW0 in FIG. 19 differs from the set of UCI bits 1800-0 for WINDOW0 in FIG. 18 in that the set of UCI bits 1900-0 for WINDOW0 in FIG. 19 has a bit to indicate an RTQ type. An RTQ type bit is also illustrated in the set of UCI bits 1900-1 for WINDOW1. An RTQ type set as “0” may be used to indicate that the RTQ feedback information bits are for consecutive TBs.

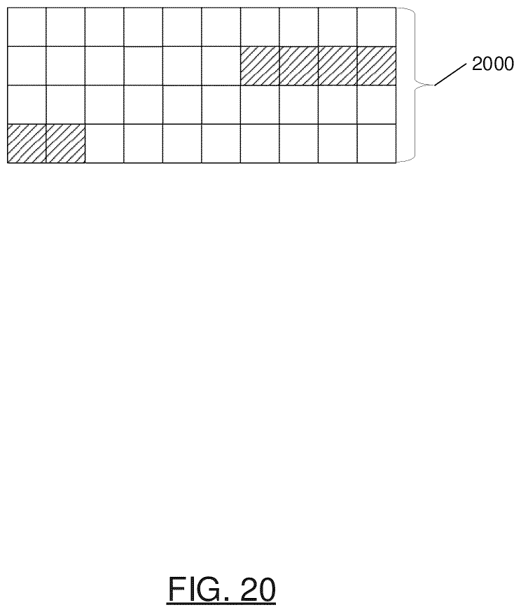

In another example, information specifying multiple groups of contiguous erroneous TBs may be included in the same UCI, wherein, for each group of contiguous erroneous TBs, a corresponding SLIV may be generated. FIG. 20 illustrates a single window 2000 with two sets of contiguous erroneous TBs.

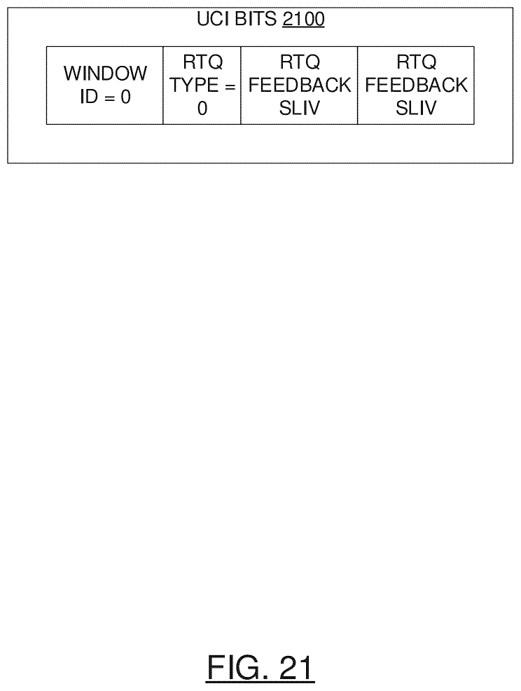

FIG. 21 illustrates an example set of UCI bits 2100 for the window 2000 of FIG. 20. The example set of UCI bits 2100 bits includes a window ID bit, an RTQ type bit, a first plurality of bits used to represent a first SLIV and a second plurality of bits used to represent a second SLIV. Indeed, ten bits may be used to represent each SLIV.

In some embodiments, the UE 110 does not wait until the end of a window of transport blocks to start generating RTQ feedback bits for the erroneously decoded transport blocks within this window. As an example, when the UE 110 has decoded (correctly or erroneously) a given number of transport blocks corresponding to the size of, e.g., a symbol (if using the source coding method for encoding), or, e.g., a partition (if using the binomial coefficient method for encoding), then the UE 110 can start generating the RTQ feedback bits for these transport blocks and transmit a PUCCH transmission, with the UCI carrying the generated RTQ feedback bits, to the NT-TRP 172.

In some embodiments, there may be a time relationship defining when the UE 110 can start generating the RTQ feedback bits, measured, e.g., from the last OFDM symbol of the PDSCH transmission carrying the last transport block and the first OFDM symbol where the UE 110 starts to generate the RTQ feedback bits. There may be a time relationship defining when the UE 110 transmits the PUCCH transmission, with the UCI carrying the generated RTQ feedback bits, measured, e.g., from the last OFDM symbol of the PDSCH transmission carrying the last transport block and the first OFDM symbol where the UE 110 transmits the PUCCH transmission.

In some embodiments, the time relationships can be defined using units, e.g., seconds, milli-seconds, micro-seconds, nano-seconds, OFDM symbols, groups of OFDM symbols, mini-slots, groups of mini-slots, slots, groups of slots. The time relationship may be specified in a specification document or the time relationship may be configured to the UE 110 by the NT-TRP 172 using higher-layer signaling (e.g., RRC signaling) or lower-layer signaling (e.g., MAC-CE signaling).

Aspects of the present application relate to protocols for a Selective Retransmission Request (SeRQ). It is anticipated that an NT-TRP 172 may use a SeRQ to retransmit RTQ-ed packets. There are aspects of the protocol for SeRQ that relate to retransmitting high priority TBs. There are aspects of the protocol for SeRQ that relate to retransmitting low priority TBs. There are aspects of the protocol for SeRQ that relate to retransmitting high priority TBs mixed with low priority TBs.

Notably, to allow a network entity to refer to specific TBs unambiguously, each TB may be associated with a Packet ID. A Packet ID may be a unique number to help a UE 110 identify a TB held in a Soft Buffer that is local to the UE 110. The Packet ID may be appended to a TB in a Packet ID field. Rather than append a Packet ID to a TB, the Packet ID for a particular TB may be provided in DCI carried in a PDCCH transmission.

Consider that a given UE 110 has been configured to transmit RTQ feedback to an NT-TRP 172. A plurality of manners by which the given UE 110 may transmit RTQ feedback to the NT-TRP 172 have been presented hereinbefore.

TBs coming from the MAC layer may have a certain QoS priority (e.g., best effort vs. voice-call). The QoS of the TBs may, of course, depend on the nature of the traffic flow. TBs of traffic associated with the best effort QoS may be referred to as “low priority TBs.” In contrast, TBs of traffic associated with the voice call QoS may be referred to as a “high priority TBs.”

In one example SeRQ protocol, for high priority TBs, it may be specified that the NT-TRP 172 is to retransmit a particular high priority TB as part of the same window in which the particular high priority TB is also sent. Such a retransmission may be understood to occur before the NT-TRP 172 has received RTQ feedback information from the UE 110. As discussed hereinbefore, TBs may be appended with a Packet ID field. The UE 110 may recognize that the Packet ID appended to the particular high priority TB is the same as the Packet ID appended to the retransmission of the particular high priority TB. Subsequently, the UE 110 may combine the particular high priority TB with the retransmission of the particular high priority TB to, thereby, decrease a probability of erroneously receiving the particular high priority TB.

Notably, the Packet ID field may be encoded separately from the TB payload. In particular, the Packet ID field may be encoded using an error-correcting code. Examples of error-correcting codes include: Bose-Chaudhuri-Hocquenghem (BCH) codes; low-density parity-check (LDPC) codes; and Polar codes.

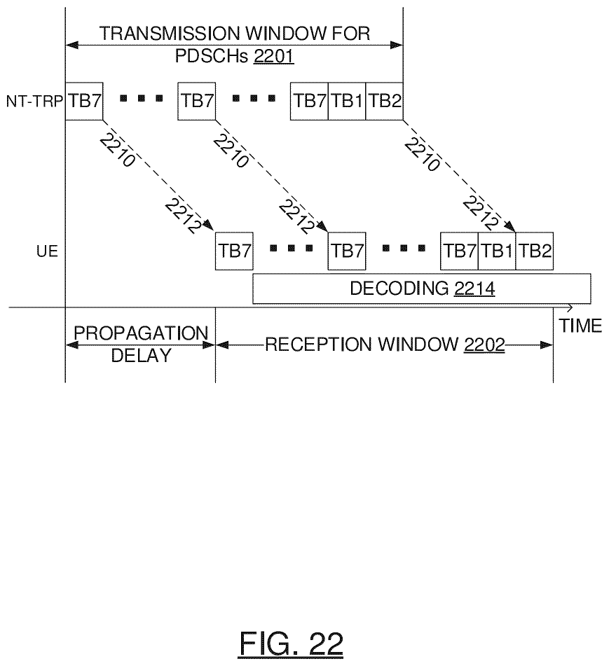

An example of a transmission event followed by a reception event is illustrated in FIG. 22. The transmission event occurs, within a transmission window for PDSCHs 2201, as the NT-TRP 172 transmits (step 2210) a plurality of TBs. It may be understood that each TB includes a TB payload and a Packet ID. For example, each TB may include an N-bit TB payload and a six-bit Packet ID. As illustrated in FIG. 22, three of the TBs transmitted in the transmission window 2201 are associated with a Packet ID with value 7. Others of the TBs transmitted in the transmission window 2201 are associated with Packet IDs with other values. FIG. 22 also illustrates a reception window 2202, representative of the receiving (step 2212), by the UE 110, of the TBs transmitted in the transmission window 2201. Upon receiving (step 2212) a TB, the UE 110 decodes the TB. The UE 110 may base RTQ feedback generation on processing the TBs received in the reception window 2202. Processing the TBs may be understood to include decoding (step 2214) the TBs. The term “decoding” is intended to represent an attempt to decode the TB, without regard to the result of the attempt. That is, decoding of the TB may be successful or unsuccessful but may still be referenced as decoding. Notably, the UE 110 may not attempt decoding a TB if the UE 110 fails to detect the corresponding PDCCH.

Restated, the NT-TRP 172 transmits (step 2210) a first TB that contains a packet with a Packet ID=7 and then retransmits (step 2210) two more TBs that also contain a packet with a Packet ID=7. Notably, the UE 110 does not have any awareness that the three TBs carry the same payload (with Packet ID=7) until after having decoded (step 2214) the Packet ID field that is appended to the three TBs. The retransmissions may contain exactly the same information bits and same redundancy bits as the first transmission (i.e., a single redundancy version may be used for all three TBs). Alternatively, the retransmissions may contain the same information bits but different redundancy bits when compared to the first transmission (i.e., distinct redundancy versions may be used for each TB). Upon receipt of the TBs, the UE 100 may run soft decoding algorithms on the TBs. The presence or absence of distinctness in the redundancy versions used may be shown to influence generation, by the UE 110, of RTQ feedback information bits.

Different UE behaviors are contemplated.

In a first behavior, each of the three TBs (with Packet ID=7) have been scheduled by a distinct PDCCH and none of the three TBs have been decoded successfully. Since the UE 110 was unable to decode any of the TBs (including the Packet ID field), the UE 110 lacks awareness that those TBs were, in fact, all the same packet. It follows that the UE 110 may generate RTQ feedback to indicate erroneous TBs in all three positions.

In a second behavior, each of the three TBs (with Packet ID=7) have been scheduled by a distinct PDCCH and none of the three TBs have been decoded successfully. However, the UE 110 has been able to decode the Packet ID field correctly for at least one of the TBs. It follows that the UE 110 may generate RTQ feedback for up to one of the TBs. The TB for which the UE 110 may generate RTQ feedback may be any one of the TB in the 1st position, the TB in the 2nd position or the TB in the last position. The generation, by the UE 110, of RTQ feedback for up to one of the TBs may be shown to reduce the number of RTQ feedback information bits.

In a third behavior, each of the three TBs (with Packet ID=7) have been scheduled by a distinct PDCCH, at least one of the TBs has been decoded successfully and, among those TBs that have not been decoded successfully, the Packet ID has not been decoded correctly. The one TB for which the UE 110 may generate RTQ feedback may be one of the TBs for which the Packet ID has not been decoded correctly.

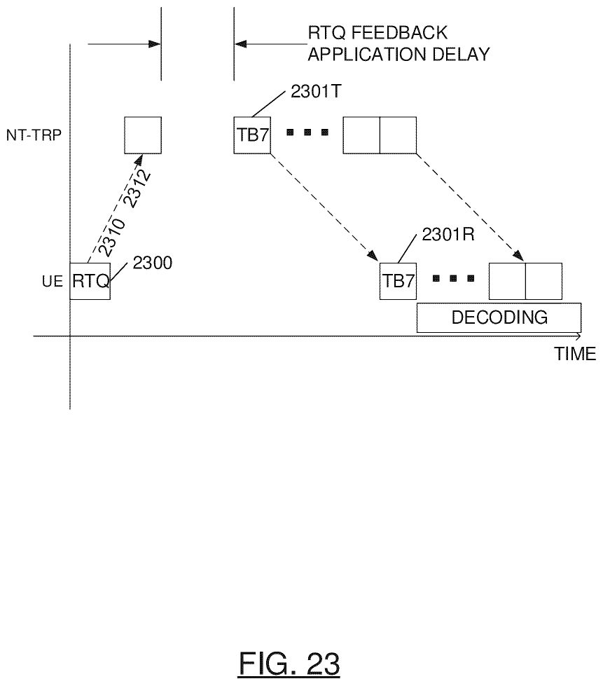

For a situation wherein the retransmission attempts, by the NT-TRP 172 during the transmission window 2201, have all failed, the UE 110 may generate RTQ feedback 2300 (see FIG. 23). The UE 110 may transmit (step 2310) a PUCCH carrying a UCI with the RTQ feedback 2300 to the NT-TRP 172. Upon receiving (step 2312) the PUCCH, the NT-TRP 172 may process the RTQ feedback 2300. The processing of the RTQ feedback 2300 may cause the NT-TRP 172 to schedule a retransmission for the TB with Packet ID=7 in a subsequent window, as illustrated as TB 2301T in FIG. 23. The time that passes between the receipt of the RTQ feedback 2300 and the retransmission of the TB 2301T with Packet ID=7 may be called an RTQ feedback application delay. As illustrated in FIG. 23, the UE 110 receives a TB 2301R with Packet ID=7. Decoding of the TB with Packet ID=7 may involve combining bits received in the received retransmission TB 2301R with bits received in the original transmissions of one or more TBs with Packet ID=7.

Aspects of the present application relate to protocols for SeRQ for retransmitting low priority TBs.

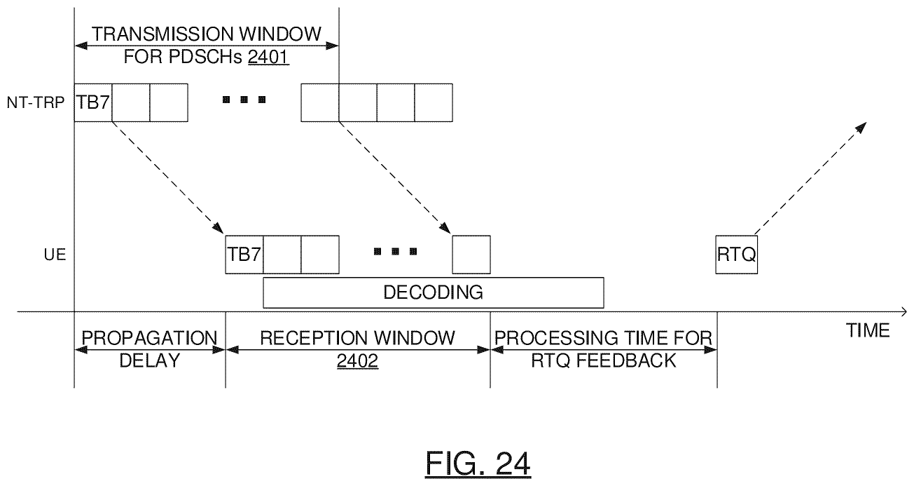

A SeRQ protocol for low priority TBs may, for example, involve an NT-TRP 172 jointly transmitting multiple redundancy versions of the same packet in one or more transmission occasions. Such redundancy version transmissions may be arranged to occur after receiving RTQ feedback information from a UE 110. As discussed hereinbefore, the NT-TRP 172 may append TBs with a Packet ID in a Packet ID field. An example of the SeRQ protocol for low priority TBs is illustrated in FIG. 24.

In the example illustrated in FIG. 24, the NT-TRP 172 transmits a first TB with a Packet ID=7, other packets are also transmitted as part of a transmission window 2401. FIG. 24 also illustrates a reception window 2402, representative of the receipt, by the UE 110, of the TBs transmitted in the transmission window 2401. The UE 110 may base RTQ feedback generation on processing the TBs received in the reception window 2402. Upon processing the TBs to obtain the RTQ feedback, the UE 110 transmits, to the NT-TRP 172, the RTQ feedback indicating, at least in part, that the TB with Packet ID=7 has been erroneously received. Responsive to receiving the RTQ feedback, the NT-TRP 172 schedules retransmissions, to the UE 110, of the TB with Packet ID=7.

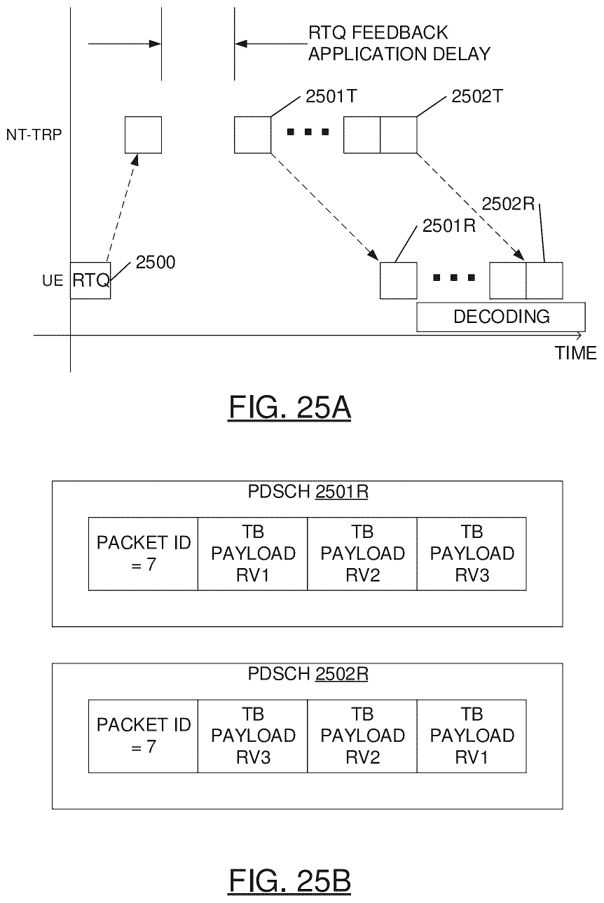

An example of the retransmissions is illustrated in FIG. 25A. The NT-TRP 172 transmits (not shown) a PDCCH scheduling a first PDSCH 2501T jointly carrying three redundancy versions of the TB with Packet ID=7. The redundancy versions may be referenced as RV1, RV2 and RV3. These redundancy versions can be transmitted using various multiplexing techniques in, for multiple examples, the time domain, the frequency domain, the spatial domain or the code domain. If necessary, the NT-TRP 172 may choose to further transmit the redundancy versions in a second PDSCH 2502T, as illustrated in FIG. 25A. The transmission of three redundancy version allows the UE 110 to decode three different copies of the same TB payload and apply soft decoding techniques to try and decode the TB payload correctly.

A DCI format in the PDCCH carries the information about the redundancy versions that are to be transmitted in each PDSCH 2501T, 2502T. For one example, the DCI may indicate, to the UE 110, that a first received PDSCH 2501R (see FIG. 25B), based on the first transmitted PDSCH 2501T has redundancy versions arranged according to a four-bit redundancy version code equaling 7. The redundancy version code equaling 7 specifies that the redundancy versions are in order {RV1, RV2, RV3}.

For another example, the DCI may indicate, to the UE 110, that a second received PDSCH 2502R (see FIG. 25B), based on the second transmitted PDSCH 2502T has redundancy versions arranged according to a four-bit redundancy version code equaling 13. The redundancy version code equaling 13 specifies that the redundancy versions are in order {RV3, RV2, RV1}.

As illustrated in FIG. 25B, the first PDSCH 2501R includes Packet ID=7. Decoding of the TB with Packet ID=7 may involve combining redundant payload bits received in the first received PDSCH 2501R with bits received in the original transmissions of TBs with Packet ID=7.

Aspects of the present application relate to a protocol for SeRQ for retransmitting high priority TBs mixed with low priority TBs.

In a manner distinct from scenarios described hereinbefore, it may be assumed that TBs contain a plurality of packets, rather than just a single packet. Among the plurality of packets, within a given TB, there may be at least one high priority packet and at least one low priority packet. Aspects of the present application relate to retransmitting high priority packets within the given TB before receiving RTQ feedback from the UE 110.

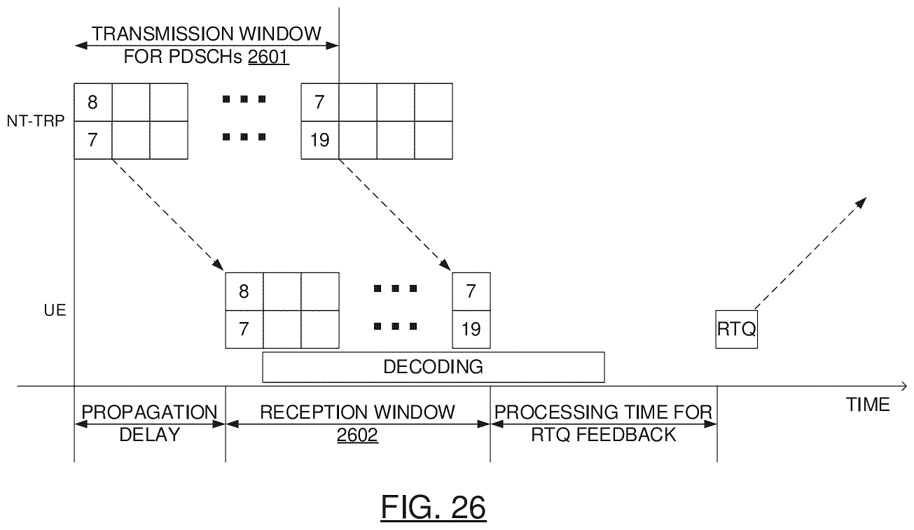

An example of this SeRQ protocol is illustrated in FIG. 26.

In the example illustrated in FIG. 26, the NT-TRP 172 transmits a PDCCH (not shown) carrying a DCI format with a QoS TB field. The presence of the QoS TB field may be arranged to indicate, to the UE 110, that the TB contains a high priority packet and a low priority packet. In the example illustrated in FIG. 26, the packet with Packet ID=7 is the high priority packet and the packets with Packet ID={8, 19} are the low priority packets.

Individual packets may be mapped to a given spot on the Soft Buffer at the UE 110. That is, upon receiving a PDSCH transmission carrying a TB with a high priority packet and a low priority packet, the UE 110 is expected to map each packet to a different location in the Soft Buffer. Such a mapping may be shown to allow the UE 110 to execute soft decoding algorithms on a per-packet granularity level. Furthermore, such a mapping may be shown to influence generation of RTQ feedback. Several different UE behaviors are contemplated for RTQ feedback generation.

In a first behavior, the UE 110 may generate RTQ feedback for high priority packets and separate RTQ feedback for low priority packets. As part of generating a UCI to carry the RTQ feedback for these packets, the UE 110 may append the UCI with a one-bit QoS priority field. The value of the bit in the QoS priority field may be interpreted, by the NT-TRP 172 as indicating High-Priority or Low-Priority.

In a second behavior, the UE 110 may generate joint RTQ feedback for high priority packets and for low priority packets. The RTQ feedback may be generated in an order that matches the order in which PDCCHs have been received. For every PDCCH that schedules a PDSCH containing a high priority packet and a low priority packet, the RTQ feedback may be generated in an order that corresponds to the order of the QoS priority of the corresponding packet. That is, for a situation wherein a high priority packet precedes a low priority packet in a given TB, an RTQ feedback information bit for the high priority packet will be arranged to precede an RTQ feedback information bit for the low priority packet and vice versa.

It may be the case that both the transmission of the high profile packet (Packet ID=7, first TB, FIG. 26) and the retransmission of the high profile packet (Packet ID=7, last TB, FIG. 26) are received, at the UE 110, erroneously. Furthermore, the transmission of the low profile packets (Packet ID=8, Packet ID=19) are decoded, at the UE 110, correctly.

Responsive to determining that the high profile packet (Packet ID=7) transmission attempts, by the NT-TRP 172 during the transmission window 2401, have all failed, the UE 110 may generate RTQ feedback and transmit, to the NT-TRP 172, a PUCCH carrying a UCI with the RTQ feedback. Upon receiving the PUCCH, the NT-TRP 172 may process the RTQ feedback and schedule a retransmission for the TB with Packet ID=7, as illustrated in FIG. 23.

Given that, in the present example, the low priority packets (Packet ID=8 and Packet ID=19) have been decoded correctly, the low priority packets need not be retransmitted. Notably, in another example, wherein the low priority packets have not been decoded correctly, the UE 110 and the NT-TRP 172 may react in the manner described hereinbefore in conjunction with FIGS. 24, 25A and 25B.

In aspects of the present application, the retransmissions of the low priority packets or high priority packets are repetitions of the packets that were transmitted at the first transmission. That is, the NT-TRP 172 retransmits exactly the same bits for the low priority packets or the high priority packets, i.e., the information bits and the redundancy bits are exactly the same as those that were transmitted at the first transmission.

In aspects of the present application, the UE 110 may support the capability of Selective Retransmission protocol and report that capability as part of its UE Capability Report, e.g., after having completed an Initial Access procedure to establish a connection with the NT-TRP 172. The UE 110 may support the capability of generating RTQ feedback as a mandatory feature without capability signaling, as a mandatory feature with capability signaling or as an optional feature with capability signaling.

In one example, the UE 110 may report the capability of generating RTQ feedback using source coding based on, e.g., Huffman coding, adaptive Huffman coding, Lempel-Ziv coding, Fano-Elias coding, Shannon coding or any other form of arithmetic coding. The capability may be reported, by the UE 110, as a 1-bit field set to 1 or “true.”

In a second example, the UE 110 may report the capability of generating RTQ feedback using the binomial coefficient-based scheme as described hereinbefore. The capability may be reported by the UE 110 as a 1-bit field set to 1 or “true.”

In a third example, the UE 110 may report the capability of generating RTQ feedback using the RTQ codebook as described hereinbefore, or using a SLIV as described hereinbefore. The capability may be reported by the UE 110 as a 1-bit field set to 1 or “true.”

It should be appreciated that one or more steps of the embodiment methods provided herein may be performed by corresponding units or modules. For example, data may be transmitted by a transmitting unit or a transmitting module. Data may be received by a receiving unit or a receiving module. Data may be processed by a processing unit or a processing module. The respective units/modules may be hardware, software, or a combination thereof. For instance, one or more of the units/modules may be an integrated circuit, such as field programmable gate arrays (FPGAs) or application-specific integrated circuits (ASICs). It will be appreciated that where the modules are software, they may be retrieved by a processor, in whole or part as needed, individually or together for processing, in single or multiple instances as required, and that the modules themselves may include instructions for further deployment and instantiation.

Although a combination of features is shown in the illustrated embodiments, not all of them need to be combined to realize the benefits of various embodiments of this disclosure. In other words, a system or method designed according to an embodiment of this disclosure will not necessarily include all of the features shown in any one of the Figures or all of the portions schematically shown in the Figures. Moreover, selected features of one example embodiment may be combined with selected features of other example embodiments.

Although this disclosure has been described with reference to illustrative embodiments, this description is not intended to be construed in a limiting sense. Various modifications and combinations of the illustrative embodiments, as well as other embodiments of the disclosure, will be apparent to persons skilled in the art upon reference to the description. It is therefore intended that the appended claims encompass any such modifications or embodiments.

What is claimed:

1. A method comprising:
receiving a plurality of transport blocks in a window, the window predefined to include a number of transport blocks;
decoding at least one transport block in the plurality of transport blocks; and
transmitting feedback corresponding to a subset of transport blocks, from the plurality of transport blocks in the window, that have not been decoded correctly.

2. The method of claim 1, wherein each transport block among the plurality of transport blocks is received in a corresponding physical downlink shared channel reception occasion.

3. The method of claim 1, further comprising:
encoding the feedback using a bitmap.

4. The method of claim 1, further comprising:
encoding the feedback using source coding.

5. The method of claim 4, wherein the using the source coding comprises:
partitioning the window into a plurality of groups of transport blocks; and
generating the feedback by encoding, for a group in the plurality of groups, a code word selected within a codebook, wherein the code word is representative of positions, in the group, of transport blocks that have not been decoded correctly in view of the number of transport blocks in the group.

6. The method of claim 5, wherein the codebook comprises a plurality of code words, wherein each code word in the plurality of code words is associated with an input symbol from a dictionary, the dictionary corresponding to the subset of transport blocks that have not been decoded correctly.

7. An apparatus comprising:
at least one processor; and
a non-transitory computer readable storage medium storing instructions that, when executed by the at least one processor, cause the apparatus to perform operations including:
receiving a plurality of transport blocks in a window, the window predefined to include a number of transport blocks;
decoding at least one transport block in the plurality of transport blocks; and
transmit feedback corresponding to a subset of transport blocks, from the plurality of transport blocks in the window, that have not been decoded correctly.

8. The apparatus of claim 7, wherein each transport block among the plurality of transport blocks is received in a corresponding physical downlink shared channel reception occasion.

9. The apparatus of claim 7, the operations further comprising:
encoding the feedback using a bitmap.

10. The apparatus of claim 7, the operations further comprising:
encoding the feedback using source coding.

11. The apparatus of claim 10, wherein the using the source coding comprises:
partitioning the window into a plurality of groups of transport blocks; and
generating the feedback by encoding, for a group in the plurality of groups, a code word selected within a codebook, wherein the code word is representative of positions, in the group, of transport blocks that have not been decoded correctly in view of the number of transport blocks in the group.

12. The apparatus of claim 11, wherein the codebook comprises a plurality of code words, wherein each code word in the plurality of code words is associated with an input symbol from a dictionary, the dictionary corresponding to the subset of transport blocks that have not been decoded correctly.

13. A method comprising:
transmitting a plurality of transport blocks in a window, the window predefined to include a number of transport blocks; and
receiving feedback corresponding to a subset of transport blocks, from the plurality of transport blocks in the window, that have not been decoded correctly.

14. The method of claim 13, further comprising:
decoding the feedback, wherein the feedback has been encoded using source coding.

15. The method of claim 14, wherein the using the source coding comprises:
partitioning the window into a plurality of groups of transport blocks; and
generating the feedback by encoding, for a group in the plurality of groups, a code word selected within a codebook, wherein the code word is representative of positions, in the group, of transport blocks that have not been decoded correctly in view of the number of transport blocks in the group.

16. The method of claim 15, wherein the codebook comprises a plurality of code words, wherein each code word in the plurality of code words is associated with an input symbol from a dictionary, the dictionary corresponding to the subset of transport blocks that have not been decoded correctly.

17. The method of claim 16, wherein the dictionary comprises a plurality of input symbols, each input symbol:
corresponding to a given probability of not decoding a corresponding transport block correctly; and
representing a position, within the group, of the corresponding transport block that has not been decoded correctly.

18. The method of claim 16, wherein the decoding comprises:
selecting the codebook from a plurality of codebooks.

19. An apparatus comprising:
at least one processor; and
a non-transitory computer readable storage medium storing instructions that, when executed by the at least one processor, cause the apparatus to perform operations including:
transmitting a plurality of transport blocks in a window, the window predefined to include a number of transport blocks; and
receiving feedback corresponding to a subset of transport blocks, from the plurality of transport blocks in the window, that have not been decoded correctly.

20. The apparatus of claim 19, the operations further comprising:
decoding the feedback, wherein the feedback has been encoded using source coding.
